(19) United States
(12) Patent Application Publication
(10) Pub. No.: US 2026/0148773 A1
(43) Pub. Date: May 28, 2026

(54) VOLTAGE CONTROL CIRCUITS, MEMORY SYSTEMS, AND VOLTAGE CONTROL METHODS

(71) Applicant: Yangtze Memory Technologies Co., Ltd., Wuhan (CN)

(72) Inventors: Xiangda Meng, Wuhan (CN); Rongrong Wu, Wuhan (CN)

(21) Appl. No.: 19/072,706

(22) Filed: Mar. 6, 2025

(30) Foreign Application Priority Data
Nov. 25, 2024 (CN) 202411699036.3

(51) Int. Cl. G11C 16/30; G11C 16/04

(52) U.S. Cl. CPC G11C 16/30; G11C 16/0483

(57) ABSTRACT

The present disclosure provides a voltage control circuit, a memory system, and a voltage control method. The voltage control circuit includes: a first voltage control sub-circuit coupled to a first power supply pin and a first voltage node; and a second voltage control sub-circuit coupled to a second power supply pin and a first voltage node. The first voltage control sub-circuit outputs a first target voltage in response to a first voltage signal received by the first power supply pin being a first power supply voltage, and the second voltage control sub-circuit disconnects a first current pathway between the second power supply pin and the first voltage node in response to a first control signal.

### CROSS-REFERENCE TO RELATED APPLICATIONS

This application claims priority to and the benefit of Chinese Patent Application 202411699036.3, filed on Nov. 25, 2024, which is hereby incorporated by reference in its entirety.

### TECHNICAL FIELD

The present disclosure relates to the field of semiconductor technology, and in particular to voltage control circuits, memory systems, and voltage control methods.

### BACKGROUND

Universal Flash Storage (UFS) uses serial data transfer technology and operates in full duplex mode, allowing read and write data transfer on the same channel. In addition, UFS supports multi-channel data transfer, where multiple channels may perform read and write data transfer simultaneously, therefore it has high transfer efficiency and is suitable for mobile devices such as smart phones, tablets, computers, etc. Mobile devices and UFS products may communicate through the UFS protocol.

### BRIEF DESCRIPTION OF THE DRAWINGS

FIG. 1A is a block diagram of an example system comprising a memory provided in an example of the present disclosure.

FIG. 1B is a schematic diagram of a memory card provided in an example of the present disclosure.

FIG. 1C is a schematic diagram of an SSD provided in an example of the present disclosure.

FIG. 2 is a schematic diagram of a memory device comprising a peripheral circuit provided in an example of the present disclosure.

FIG. 3 is a schematic diagram of a peripheral circuit provided in an example of the present disclosure.

FIG. 4 is a schematic diagram of a memory system comprising a memory controller provided in an example of the present disclosure.

FIG. 5 is a schematic diagram of a memory system product provided in an example of the present disclosure.

FIG. 6 is a schematic diagram of another memory system product provided in an example of the present disclosure.

FIG. 7 is a first schematic diagram of a memory system comprising a voltage control circuit provided in an example of the present disclosure.

FIG. 8 is a first schematic diagram of a voltage control circuit provided in an example of the present disclosure.

FIG. 9 is a second schematic diagram of a voltage control circuit provided in an example of the present disclosure.

FIG. 10 is a third schematic diagram of a voltage control circuit provided in an example of the present disclosure.

FIG. 11 is a fourth schematic diagram of a voltage control circuit provided in an example of the present disclosure.

FIG. 12 is a fifth schematic diagram of a voltage control circuit provided in an example of the present disclosure.

FIG. 13 is a second schematic diagram of a memory system comprising a voltage control circuit provided in an example of the present disclosure.

FIG. 14 is a third schematic diagram of a memory system comprising a voltage control circuit provided in an example of the present disclosure.

FIG. 15 is a sixth schematic diagram of a voltage control circuit provided in an example of the present disclosure.

FIG. 16 is a seventh schematic diagram of a voltage control circuit provided in an example of the present disclosure.

FIG. 17 is an eighth schematic diagram of a voltage control circuit provided in an example of the present disclosure.

FIG. 18 is a ninth schematic diagram of a voltage control circuit provided in an example of the present disclosure.

FIG. 19 is a fourth schematic diagram of a memory system comprising a voltage control circuit provided in an example of the present disclosure.

FIG. 20 is a fifth schematic diagram of a memory system comprising a voltage control circuit provided in an example of the present disclosure.

FIG. 21 is a schematic diagram of a Universal Flash Storage provided in an example of the present disclosure.

FIG. 22 is a first flow diagram of a voltage control method provided in an example of the present disclosure.

FIG. 23 is a second flow diagram of a voltage control method provided in an example of the present disclosure.

FIG. 24 is a third flow diagram of a voltage control method provided in an example of the present disclosure.

FIG. 25 is a fourth flow diagram of a voltage control method provided in an example of the present disclosure.

FIG. 26 is a fifth flow diagram of a voltage control method provided in an example of the present disclosure.

FIG. 27 is a sixth flow diagram of a voltage control method provided in an example of the present disclosure.

### DETAILED DESCRIPTION

Due to the rapid development of mobile devices, different mobile devices may provide different power supply methods to UFS products according to different UFS protocols, and therefore memory manufacturers need to prepare UFS products with multiple sets of power supply methods, resulting in high research and development costs.

Example implementations disclosed in the present disclosure will be described in more detail below with reference to the accompanying drawings. Although example implementations of the present disclosure are shown in the accompanying drawings, it should be understood that the present disclosure may be implemented in various forms and should not be limited by the specific examples set forth herein. Rather, these examples are provided for a more thorough understanding of the present disclosure and will fully convey the scope of the present disclosure to those skilled in the art.

In the following description, numerous specific details are provided for a more thorough understanding of the present disclosure. However, it will be apparent to those skilled in the art that the present disclosure may be implemented without one or more of these details. In other examples, in order to avoid confusion with the present disclosure, some technical features well known in the art have not been described; That is, not all features of actual implementations will be described here, and well-known functions and structures will not be described in detail.

The same reference number indicates the same element throughout the figures.

It should be understood that spatial relationship terms such as “below”, “under”, “underlying”, “underneath”, “over”, “on”, etc. may be used here for ease of description to describe the relationship between one element or feature and other elements or features shown in the figures. It should be understood that in addition to the orientation shown in the figures, spatial relationship terms intend to further include different orientations of a device in use and operation. For example, if the device in the figure is flipped, then the element or feature described as “below” or “under” or “underneath” another element will be oriented “above” the other element or feature. Therefore, the example terms such as “below” and “under” may include both upper and lower orientations. The device may be oriented additionally (rotated 90 degrees or otherwise oriented) and spatial description terms used herein are interpreted accordingly.

The terms used herein are only for the purpose of describing specific examples and is not intended as a limitation of the present disclosure. When used herein, “a”, “an”, and “the” in singular form are also intended to include the plural form, unless the context clearly indicates otherwise. It should also be understood that the terms “comprise” and/or “include”, when used in this specification, specify the presence of the described features, integers, steps, operations, elements, and/or components, but do not exclude the presence or addition of one or more other features, integers, steps, operations, elements, components, and/or groups. When used herein, the term “and/or” includes any and all combinations of the related items listed.

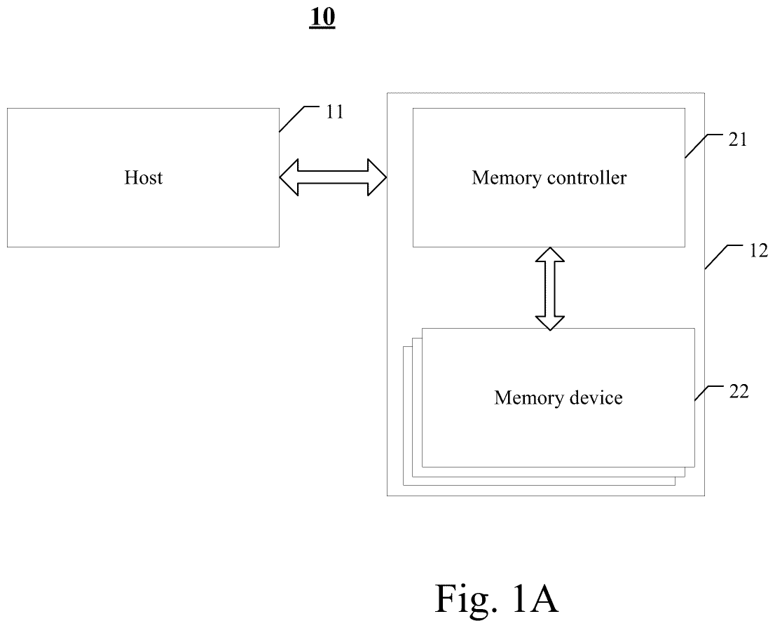

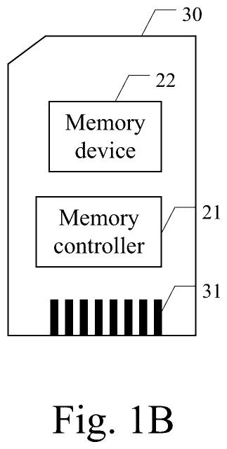

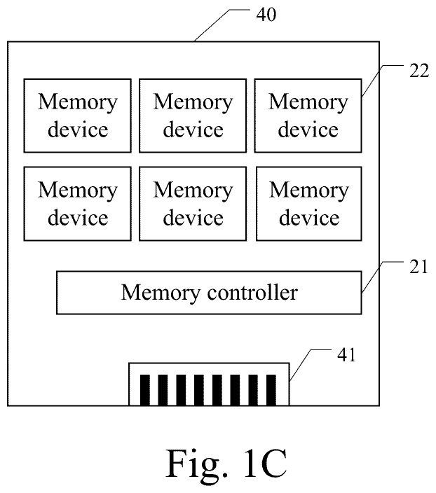

FIG. 1a is a block diagram of an example system comprising a memory provided in an example of the present disclosure. The example system 10 may include a host 11 and a memory system 12, and the example system 10 may include but is not limited to a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device with memory device 22 therein; and host 11 may be a processor of an electronic device such as a Central Processing Unit (CPU) or a System on Chip (SoC) such as an Application Processor (AP).

In an example of the present disclosure, the host 11 may be configured to send or receive data to or from the memory system 12. Here, the memory system 12 may include a memory controller 21 and one or more memory devices 22. The memory device 22 may include but is not limited to NAND Flash Memory, Vertical NAND Flash Memory, NOR Flash Memory, Dynamic Random Access Memory (DRAM), Ferroelectric Random Access Memory (FRAM), Magneto resistive Random Access Memory (MRAM), Phase Change Random Access Memory (PCRAM), Resistive Random Access Memory (RRAM), Nano Random Access Memory (NRAM), etc.

In an example of the present disclosure, the memory controller 21 may be coupled to the memory device 22 and the host 11 and configured to control the memory device 22. For example, the memory controller 21 may be designed to operate in low duty cycle environments, such as Secure Digital (SD) cards, Compact Flash (CF) cards, Universal Serial Bus (USB) flash drives, or other media used in electronic devices such as personal calculators, digital cameras, mobile phones, etc. In some examples, the memory controller 21 may also be designed to operate in high duty cycle environments, such as Solid State Disk (SSD) or Embedded Multi Media Card (eMMC), and SSD or eMMC may be used as data storage for mobile devices such as smart phones, tablets, laptop computers, and enterprise storage arrays.

Furthermore, the memory controller 21 may manage data in the memory device 22 and communicate with the host. The memory controller 21 may be configured to control operations of the memory device 22, such as reading, erasing, and programming; and may be configured to manage various functions related to data stored or to be stored in the memory device 22, including but not limited to bad block management, garbage collection, logical to physical address translation, wear leveling, etc.; and may also be configured to process error checking and correction (ECC) codes for data read from or written to the memory device 22. In addition, the memory controller 21 may also perform any other suitable function, such as formatting the memory device 22, or communicating with external devices (e.g., host 11 in FIG. 1A) according to a specific communication protocol. For example, the memory controller 21 may communicate with an external host through at least one of various interface protocols, such as USB protocol, MMC protocol, Peripheral Component Interconnect (PCI) protocol, PCI Express (PCI-E) protocol, Advanced Technology Attachment (ATA) protocol, Serial ATA protocol, Parallel ATA protocol, Small Computer Small Interface (SCSI) protocol, Enhanced Small Disk Interface (ESDI) protocol, Integrated Drive Electronics (IDE) protocol, Firewire protocol, etc.

In an example of the present disclosure, the memory controller 21 and one or more memory devices 22 may be integrated into various types of storage devices, such as being included in the same package (e.g., Universal Flash Storage (UFS) package or eMMC package). That is, the memory system 12 may be implemented and packaged into different types of end electronic products. As shown in FIG. 1B, the memory controller 21 and a single memory device 22 may be integrated together to form a memory card 30. Memory card 30 may include PC card (Personal Computer Memory Card International Association), CF card, Smart Media (SM) card, memory stick, Multi Media Card (MMC), Reduced Size MMC (RS-MMC), MMCmicro, SD card (SD, miniSD, microSD, Secure Digital High Capacity (SDHC)), UFS, etc. The memory card 30 may further include a memory card connector 31 that couples the memory card 30 to a host (e.g., host 11 in FIG. 1A). In another example as shown in FIG. 1C, the memory controller 21 and multiple memory devices 22 may be integrated together to form the SSD 40. The SSD 40 may further include an SSD connector 41 that couples the SSD 40 to a host (e.g., host 11 in FIG. 1A). In some implementations, the storage capacity and/or operating speed of SSD 40 is greater than that of memory card 30.

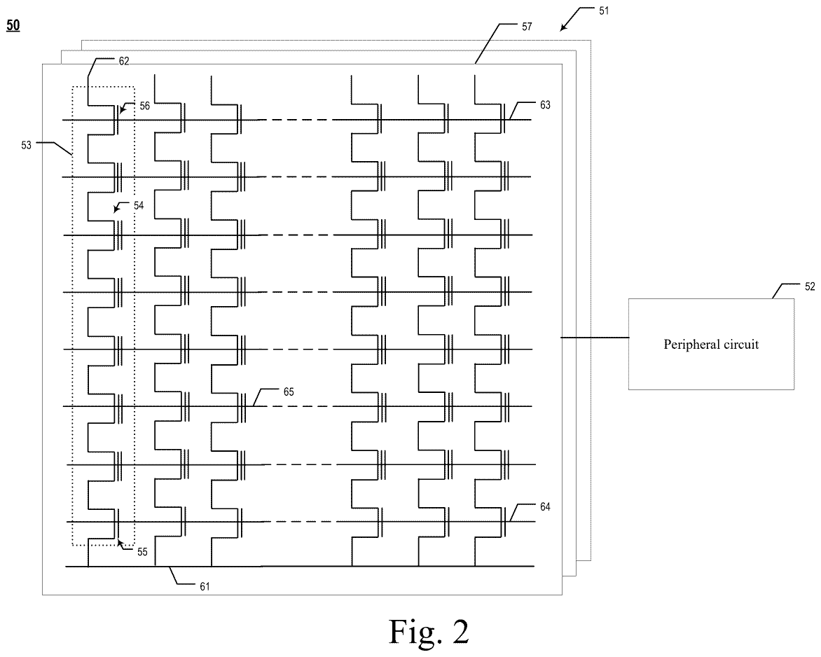

It should be noted that the memory according to an example of the present disclosure may be a semiconductor memory, which is a solid-state electronic device fabricated by a semiconductor integrated circuit process to store data information. FIG. 2 is a schematic diagram of a memory device comprising a peripheral circuit provided in an example of the present disclosure, and the memory device 50 may be the memory device 22 in FIGS. 1A to 1C. As shown in FIG. 2, the memory device 50 may include a memory cell array 51 and a peripheral circuit 52 coupled to the memory cell array 51. Here, the memory cell array may be a NAND flash memory cell array, wherein memory cells are arranged in the form of an array of NAND memory strings 53, each of which extends vertically above the substrate. In some examples, each NAND memory string 53 may include multiple memory cells 54 coupled in series and stacked vertically, wherein each memory cell 54 may maintain continuous analog values, such as voltage or charge, depending on the number of electrons trapped within the memory cell area. In addition, each memory cell 54 in the above-mentioned memory cell array 51 may be a floating gate type memory cell including a floating gate transistor, or a charge trapping type memory cell including a charge trapping transistor.

In an example of the present disclosure, the above-mentioned memory cell 54 may be a single level cell (SLC) that has two possible storage states and therefore may store one bit of data. For example, the first storage state “0” may correspond to a first range of threshold voltage, and the second storage state “1” may correspond to a second range of threshold voltage. In other examples, each memory cell 54 may be a multi-level memory cell (MLC) capable of storing more than one bit of data in more than four storage states. For example, MLC may store two bits per cell, three bits per cell (also known as Triple Level Cell (TLC)), or four bits per cell (also known as Quad Level Cell (QLC)). Each MLC may be programmed to a range of possible nominal storage values. For example, if each MLC stores two bits of data, the MLC may be programmed to program a memory cell from an erase state to one of three possible storage states by writing one of the three possible nominal storage values to the memory cell, wherein the fourth nominal storage value may be used to erase the state.

As shown in FIG. 2, each NAND memory string 53 may include a source select transistor 55 at its source terminal and a drain select transistor 56 at its drain terminal. The source select transistor 55 is also known as a bottom select transistor, and the drain select transistor 56 is also known as a top select transistor. The source select transistor 55 and the drain select transistor 56 may be configured to activate a selected NAND memory string 53 (a column of an array) during read and program operations.

In some implementations, the sources of NAND memory strings 53 in the same block 57 are coupled through the same source line (SL) 61 (e.g., a common source line). In other words, according to some examples, all NAND memory strings 53 in the same block 57 have an array common source (ACS). According to some examples, the drain select transistor 56 of each NAND memory string 53 is coupled to a corresponding bit line (BL) 62, from which data may be read or written via an output bus (not shown).

In some examples, each NAND memory string 53 is configured to be selected or deselected by applying a select voltage (e.g., higher than the threshold voltage of the drain select transistor 56) or a deselect voltage (e.g., 0V) to the gate of the corresponding drain select transistor 56 via one or more drain select gate lines (DSG lines) 63; and/or by applying a select voltage (e.g., higher than the threshold voltage of the source select transistor 55) or a deselect voltage (e.g., 0V) to the gate of the corresponding source select transistor 55 via one or more source select gate lines (SSG lines) 64. NAND memory string 53 may therefore be distinguished as a selected NAND memory string or an unselected NAND memory string, wherein the select voltage may also be referred to as a control turn-on voltage, used to turn on the corresponding transistor, and the deselect voltage may also be referred to as a control turn-off voltage, used to turn off the corresponding transistor.

In some examples, memory cells 54 of adjacent NAND memory strings 53 may be coupled through word lines 65, which select which row of memory cells 54 is affected by read and program operations.

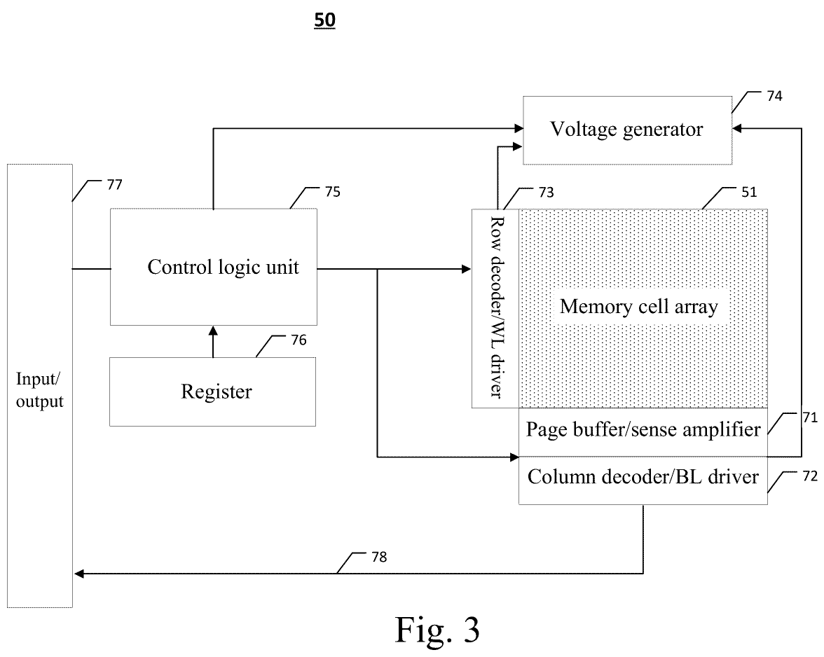

As shown in FIG. 2, peripheral circuit 52 may be coupled to memory cell array 51 through bit line 62, word line (WL) 65, source line 61, source select gate line 64, and drain select gate line 63. The peripheral circuit 52 may include any suitable analog, digital, and mixed signal circuit for implementing write and read operations of the memory cell array 51 by applying voltage and/or current signals to each target memory cell 54 and sensing voltage and/or current signals from each target memory cell 54 via bit line 62, word line 65, source line 61, source select gate line 64, and drain select gate line 63. The peripheral circuit 52 may include various types of peripheral circuits formed using the metal oxide semiconductor (MOS) technology. For example, FIG. 3 is a schematic diagram of a peripheral circuit provided in an example of the present disclosure. The peripheral circuit includes page buffer/sense amplifier 71, column decoder/BL driver 72, row decoder/WL driver 73, voltage generator 74, control logic unit 75, register 76, input/output 77, and data bus 78. It should be understood that in some examples, additional peripheral circuits not shown in FIG. 3 may also be included.

The page buffer/sense amplifier 71 may be configured to read and program (write) data from or to the memory cell array 51 according to control signals from the control logic unit 75. In one example, the page buffer/sense amplifier 71 may store one page of program data (write data) to be programmed into one page of the memory cell array 51. In another example, the page buffer/sense amplifier 71 may perform a program verification operation to ensure that data has been correctly programmed into the memory cell 54 coupled to the selected word line 65. In yet another example, the page buffer/sense amplifier 71 may also sense low-power signals representing data bits stored in the memory cell 54 from the bit line 62, and amplify a small voltage swing to a recognizable logic level during read operations.

The column decoder/BL driver 72 may be configured to be controlled by the control logic unit 75 and select one or more NAND memory strings 53 by applying bit line voltages generated from the voltage generator 74.

The row decoder/word WL driver 73 may be configured to be controlled by the control logic unit 75, and select/deselect block 57 of the memory cell array 51 and select/deselect the word line 65 in block 57 according to a control signal generated by the control logic unit. The row decoder/WL driver 73 may also be configured to use different word line voltages generated from the voltage generator 74 to drive the word line 65. In some examples, the row decoder/WL driver 73 may also select/deselect the source select gate line 64 and the drain select gate line 63. The row decoder/WL driver 73 is configured to use different SSG line voltages generated from the voltage generator 74 to drive the source select gate line 64, and/or use different DSG line voltages generated from the voltage generator 74 to drive the drain select gate line 63.

The voltage generator 74 may be configured to be controlled by the control logic unit 75 and generate various word line voltages (e.g., read voltage, program voltage, pass voltage, verify voltage, etc.), bit line voltages, ground voltages, various SSG line voltages (e.g., select voltages, deselect voltages), and various DSG line voltages (e.g., select voltages, deselect voltages) to be supplied to the memory cell array 51.

The control logic unit 75 may be coupled to each peripheral circuit portion described above and configured to control the operations of each peripheral circuit portion. The register 76 may be coupled to the control logic unit 75 and includes a status register, a command register, and an address register to store status information, command operation codes, and command addresses configured to control the operations of the peripheral circuit. In some implementations, the control logic unit 75 may receive a program command issued by a memory controller (e.g., memory controller 21 in any of FIGS. 1A to 1C) and send a control signal to various peripheral circuit portions, such as row decoder/WL driver 73, column decoder/BL driver 72, and voltage generator 74, to perform program operations on the source select transistor coupled to the source select gate line.

The input/output (I/O) 77 may be coupled to the control logic unit 75 and act as a control buffer to buffer and relay control commands (e.g., program commands) received from a memory controller or host to the control logic unit 75, and buffer and relay status information received from the control logic unit 75 to the memory controller or host. The input/output 77 may also be coupled to the column decoder/BL driver 72 via the data bus 78, and act as a data input/output interface and data buffer to buffer data and relay the data to the memory cell array 51 or relay or buffer data from the memory cell array 51.

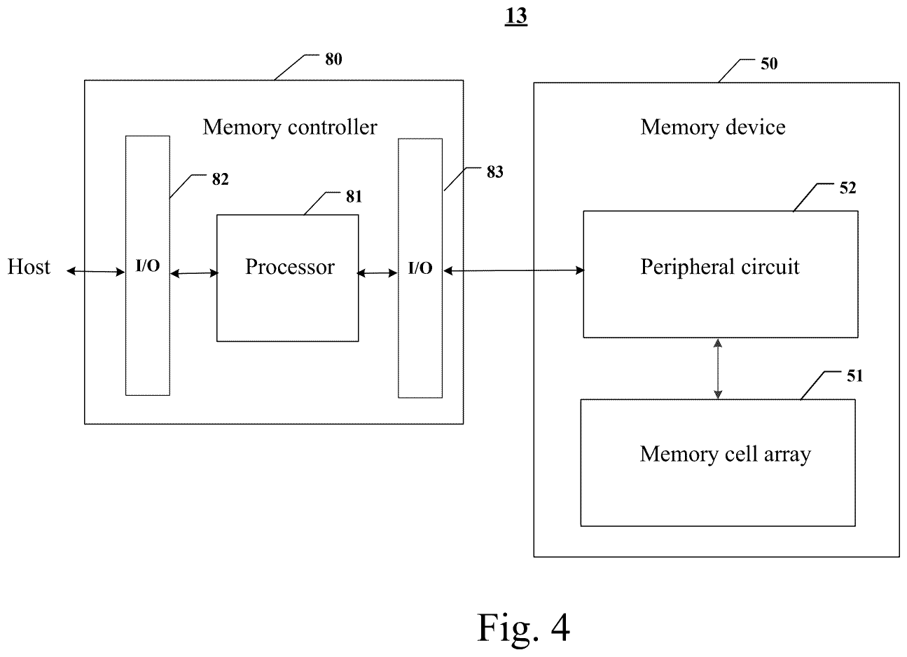

FIG. 4 is a schematic diagram of a memory system comprising a memory controller provided in an example of the present disclosure. The memory system 13 may be the memory system 12 in FIG. 1A, the memory card 30 in FIG. 1B, the SSD 40 in FIG. 1C, or the Universal Flash Storage (UFS), etc. As shown in FIG. 4, the memory system 13 may include a memory device 50 and a memory controller 80 coupled to the memory device 50 and a host (e.g., host 11 in FIG. 1A). The memory controller 80 may include a processor 81, front-end I/O 82, and back-end I/O 83. The front-end I/O 82 communicates with the host, receives commands and data information sent by the host, and parses the commands. The front-end I/O 82 may communicate with the host through PCIe protocol, Non-Volatile Memory Express (NVMe) protocol, UFS protocol, etc.

The back-end I/O 83 is configured to manage data writing or data reading to or from the memory device 50. The peripheral circuit of the memory device 50 includes I/O (e.g., input/output 77 in FIG. 3), and the I/O in the peripheral circuit may communicate with the back-end I/O 83 in the memory controller through Opening NAND Flash Interface (ONFI) protocol, toggle protocol, etc. For example, the back-end I/O 83 of the memory controller may be configured with multiple channels, coupled to multiple memory devices 50, to control data reading and writing of multiple memory devices. The processor 81 is coupled to the front-end I/O 82 and back-end I/O 83, and may control the overall operation of memory system 13. The processor 81 may use firmware to control the overall operation of memory system 13, such as performing tasks such as garbage collection, wear leveling, bad block management, read disturb management, and so on.

The Universal Flash Storage is a memory system that packages flash memories (such as NAND flash memories, or also known as memory devices) and flash controllers (such as memory controllers) together. The Universal Flash Storage communicates with the host through a Universal Flash Storage (UFS) standard, allowing the host to access data. In the early UFS standards, three sets of power supply voltages were specified: Vcc, Vccq, and Vccq2, wherein Vcc is designated to supply power to flash memories, Vccq is designated to supply power to flash input/output and controller cores, and Vccq2 is designated to supply power to low-voltage modules such as M-PHY.

The controller core may handle various operations for performing memory operations on the memory device. In some examples, the controller core may decrypt commands from the host and may handle various operations such as memory allocation, signal generation, and storing and calling data for memory operations (e.g., read, write, or erase operations) corresponding to the commands. For example, the controller core may be the processor 81 in FIG. 4.

The UFS standard includes a UFS Command Set Layer (USC), a UFS Transport Layer (UTP), and a UFS Interconnect Layer (UIC). UIC includes a link layer and a physical layer (M-PHY), and the physical layer of UIC is defined according to the Mobile Industry Processor Interface (MIPI) specification.

M-PHY is a physical layer module in front-end I/O (such as front-end I/O 82 in FIG. 4) that enables the interconnection of a host and a memory system at the physical layer. The M-PHY of the memory controller includes a transmitter and a receiver, which are coupled to a receiver and a transmitter of the M-PHY layer in the host to establish a data channel with the host for data transmission and reception.

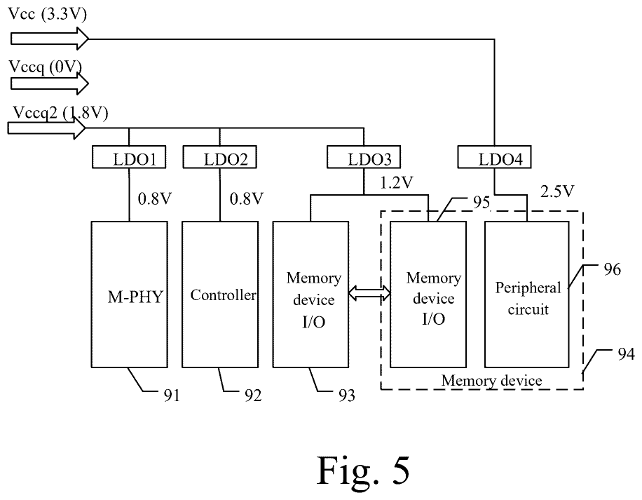

With the continuous iterative evolution of UFS products, in some UFS products, such as those based on UFS2.2 standard, the power supply scheme becomes Vcc=3.3V and Vccq2=1.8V. FIG. 5 is a schematic diagram of a memory system product provided in an example of the present disclosure. Each of M-PHY 91, controller core 92, memory device I/O 93, and four voltage regulators LDO1, LDO2, LDO3, and LDO4, which are not included in the memory device 94 in FIG. 5, belongs to the memory controller. As shown in FIG. 5, Vcc is 3.3V, which supplies power to the peripheral circuit 96 of the memory device 94 except for the input/output (I/O) 95 after being reduced to 2.5V by voltage regulator LDO4. Vccq2 is 1.8V, which supplies power to low-voltage modules such as M-PHY 91 after being reduced to 0.8V by the voltage regulator LDO1, supplies power to controller core 92 after being reduced to 0.8V by the voltage regulator LDO2, and supplies power to memory device I/O 93 in the memory controller and memory device I/O 95 in memory device 94 after being reduced to 1.2V by the voltage regulator LDO3.

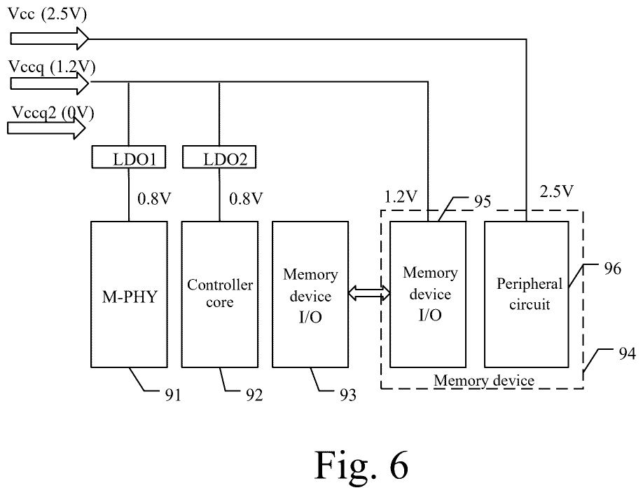

In other newer generation UFS products, such as those based on UFS3.1 standard, the power supply scheme becomes Vcc=2.5V, Vccq=1.2V. FIG. 6 is a schematic diagram of another memory system product provided in an example of the present disclosure. Each of M-PHY 91, controller core 92, memory device I/O 93, and two voltage regulators LDO1 and LDO2, which are not included in the memory device 94 in FIG. 6, belongs to the memory controller. As shown in FIG. 6, Vcc is 2.5V, which directly supplies power to the peripheral circuit 96 in the memory device 94 except for the memory device I/O 95. Vccq is 1.2V, which directly supplies power to the memory device I/O 95 in the memory device 94, and on the other hand, supplies power to low-voltage modules such as M-PHY 91 after being reduced to 0.8V by the voltage regulator LDO1, and supplies power to the controller core 92 after being reduced to 0.8V by the voltage regulator LDO2. The memory device I/O 93 in the memory controller may also be powered by Vccq. For example, the memory device I/O 93 in the memory controller in FIGS. 5 and 6 may be the back-end I/O 83 in FIG. 4. The memory device I/O 95 in the memory device 94 in FIGS. 5 and 6 may be the input/output 77 in FIG. 3. The memory device I/O 95 and peripheral circuit 96 in the memory device 94 in FIGS. 5 and 6 jointly constitute the peripheral circuit 52 shown in FIG. 2 or 4.

The two UFS products are from two adjacent generations and should be interchangeable with each other. However, due to the obvious difference in power supply schemes, the application platform (such as mobile phone motherboards) is unable to switch Vcc, Vccq or Vccq2 voltage. An application platform designed to be compatible with two generations of UFS products will require a significant increase in costs. Therefore, the common solution is that memory companies need to design two sets of UFS products on the same generation of NAND flash memory, providing different customers with different application platforms.

In addition, during the design of two sets of UFS products, it is desirable to use the controller of a newer generation UFS product with more mature applications to quickly complete the design of a previous generation UFS product. But some issues arise as the following: first, the packaging scheme needs to be redesigned, such as adding voltage regulators LDO3, LDO4, which may increase design costs; Second, although the application of the newer generation product is relatively mature, in order to design the previous generation product with the same controller, a common approach is to start from the packaging design, re-project, and go through trial production, testing, debugging, etc., which requires more workloads and resources.

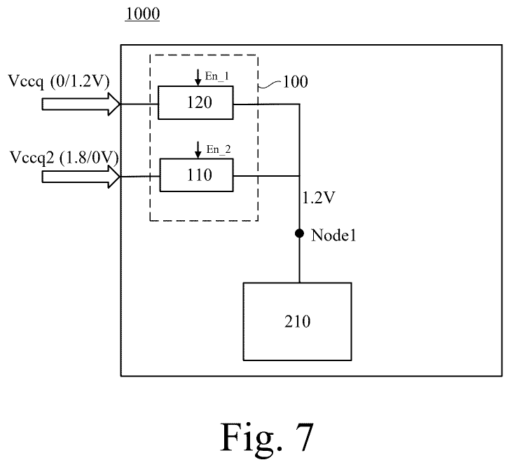

In view of this, examples of the present disclosure provide a memory system that may simultaneously support both two power supply schemes described above. FIG. 7 is a first schematic diagram of a memory system comprising a voltage control circuit provided in an example of the present disclosure. As shown in FIG. 7, the memory system 1000 includes a first device 210 and a voltage control circuit 100. The first device 210 is coupled to the first voltage node Node1. The voltage control circuit 100 includes a first voltage control sub-circuit 110 and a second voltage control sub-circuit 120. The first voltage control sub-circuit 110 is coupled to the first power supply pin Vccq2 and the first voltage node Node1, and the second voltage control sub-circuit 120 is coupled to the second power supply pin Vccq and the first voltage node Node1.

The first voltage control sub-circuit 110 is configured to output a first target voltage (e.g., 1.2V) in response to a first voltage signal received by the first power supply pin Vccq2 being a first power supply voltage (e.g., 1.8V), and the second voltage control sub-circuit 120 is configured to disconnect a first current pathway between the second power supply pin Vccq and the first voltage node Node1 in response to a first control signal En_1; and/or the second voltage control sub-circuit 120 is configured to output a first target voltage in response to a second voltage signal received by the second power supply pin Vccq being a second power supply voltage (e.g., 1.2V), and the first voltage control sub-circuit 110 is configured to disconnect a second current pathway between the first power supply pin Vccq2 and the first voltage node Node1 in response to a second control signal En_2.

The first target voltage is the operating voltage of the first device 210. At least one of the first power supply voltage and the second power supply voltage is different from the first target voltage, and the purpose of the voltage control circuit is to regulate both the first power supply voltage and the second power supply voltage to the first target voltage. Thus, when the memory system is integrated into an application platform, the voltage control circuit in the memory system may provide the first target voltage to the first device regardless of whether the power supply scheme of the application platform provides the first power supply voltage to the first power supply pin or the second power supply voltage to the second power supply pin. As such, a memory system may be compatible with two power supply schemes without providing two memory systems for the two power supply schemes, thereby reducing research and development investment, saving research and development costs, and improving platform compatibility and competitiveness of products.

In some examples, the power supply scheme of an application platform is fixed, that is, the application platform may only choose either a first power supply scheme or a second power supply scheme. In the first power supply scheme, the application platform provides the first power supply voltage to the first power supply pin, and the memory system correspondingly fixedly selects the first voltage control sub-circuit to output the first target voltage. In the second power supply scheme, the application platform provides the second power supply voltage to the second power supply pin, and the memory system correspondingly fixedly selects the second voltage control sub-circuit to output the first target voltage. In other examples, if the application platform can switch between the first power supply scheme and the second power supply scheme, the memory system may correspondingly switch the selection of the first voltage control sub-circuit and the second voltage control sub-circuit to output the first target voltage.

Continuing to refer to FIG. 7, in the first power supply scheme, when the first voltage control sub-circuit 110 outputs the first target voltage, the second voltage control sub-circuit 120, under the action of the first control signal En1, disconnects the first current pathway between the second power supply pin Vccq and the first voltage node Node1, so as to prevent the second voltage signal of the second power supply pin Vccq from affecting the voltage of the first voltage node Node1 to generate an additional voltage rise or drop, and thus to prevent an inaccurate output of the first target voltage. For example, in FIG. 7, when the first power supply pin Vccq2 receives the first power supply voltage, the input voltage of the second power supply pin Vccq is 0V. At this point, if the first current pathway is not disconnected, a current may be generated from the first voltage node to the second power supply pin, resulting in a voltage drop at the first voltage node. In other words, disconnecting the first current pathway from the second power supply pin to the first voltage node may effectively prevent the current at the first voltage node from flowing back to the second power supply pin, thus avoiding generation of an additional voltage drop.

The first control signal En_1 may be generated internally in a memory system or provided by an application platform. In some examples, the first control signal En_1 is generated internally in a memory system. For example, when the first power supply scheme is determined to be adopted, the controller in the memory system may control the disconnection of the first current pathway through the first control signal En_1.

In other examples, the first control signal En_1 is provided by an application platform. For example, the first control signal En_1 is a second voltage signal received by the second power supply pin, and the second voltage control sub-circuit 120 disconnects the first current pathway in response to the second voltage signal being a first idle voltage.

In the first power supply scheme, the application platform synchronously provides the first power supply voltage to the first power supply pin Vccq2 and the first idle voltage (e.g., 0V) to the second power supply pin Vccq. The second voltage control sub-circuit 120 disconnects the first current pathway when receiving the first idle voltage. Such an arrangement does not require to add additional control circuits and control signals into the application platform and memory system, simplifies circuit design, does not make significant changes to existing products, and saves costs such as testing and debugging.

It should be understood that in another example, the first control signal En_1 may also be a first voltage signal received by the first power supply pin, and the second voltage control sub-circuit 120 disconnects the first current pathway in response to the first voltage signal being a first power supply voltage. That is, when the application platform provides the first power supply voltage to the first power supply pin, the first voltage control sub-circuit 110 outputs the first target voltage, and the second voltage control sub-circuit 120 disconnects the first current pathway. Such an arrangement does not require to add additional control circuits and signals into the application platform and memory system, which may simplify circuit design and save footprint.

Continuing to refer to FIG. 7, in the second power supply scheme, when the second voltage control sub-circuit 120 outputs the first target voltage, the first voltage control sub-circuit 110, under the action of the second control signal En_2, disconnects the second current pathway between the first power supply pin Vccq2 and the first voltage node Node1, so as to prevent the first voltage signal of the first power supply pin Vccq2 from affecting the voltage of the first voltage node Node1 to generate an additional voltage rise or drop, and thus to prevent an inaccurate output of the first target voltage. For example, in FIG. 7, when the second power supply pin Vccq receives a second power supply voltage (e.g., 1.2V), the input voltage of the first power supply pin Vccq2 is 0V. At this point, if the first current pathway is not disconnected, a current may be generated from the first voltage node Node1 to the first power supply pin Vccq2, resulting in a voltage drop at the first voltage node Node1. In this example, disconnecting the second current pathway from the first power supply pin Vccq2 to the first voltage node Node1 may effectively prevent the current from the first voltage node Node1 from flowing back to the first power supply pin Vccq2, thus avoiding generation of an additional voltage drop.

The second control signal En_2 may be provided by an application platform or internally provided by a memory system. In some examples, the second control signal is generated internally in a memory system. For example, when the second power supply scheme is determined to be adopted, the controller in the memory system may control the disconnection of the second current pathway through the second control signal En_2.

In other examples, the second control signal En_2 is provided by an application platform. For example, the second control signal En_2 is a first voltage signal received by the first power supply pin, and the first voltage control sub-circuit 110 disconnects the second current pathway in response to the first voltage signal being a second idle voltage.

In this example, the second control signal En_2 is not an additional signal provided by the application platform, but a second idle voltage synchronously received using the first power supply pin Vccq2 to control the disconnection of the second current pathway. This approach does not require to add additional control circuits or signals into the application platform and memory system, simplifies circuit design, does not make significant changes to existing products, and saves costs such as testing and debugging. For example, the second idle voltage is a ground voltage of 0V.

It should be understood that in another example, the second control signal En_2 may also be a second voltage signal. Specifically, the first voltage control sub-circuit 110 is also coupled to the second power supply pin Vccq and disconnects the second current pathway in response to the second voltage signal being a second power supply voltage. Such an arrangement also does not require to add additional control circuits and signals into the application platform and memory system, which may simplify circuit design and save footprint.

Here, it should be noted that in practical operations, in one specific implementation, the first control signal En_1 may be the first control signal in any of the above examples, and the second control signal En_2 may be the second control signal in any of the above examples, which is not limited in the present disclosure. For example, in the first implementation, the first control signal En_1 may be a second voltage signal, and the second control signal En_2 may be a first voltage signal. In the second implementation, each of the first control signal En_1 and the second control signal En_2 is a first voltage signal. In the third implementation, each of the first control signal En_1 and the second control signal En_2 is a second voltage signal. In the fourth implementation, the first control signal En_1 may be a first voltage signal, and the second control signal En_2 may be a second voltage signal.

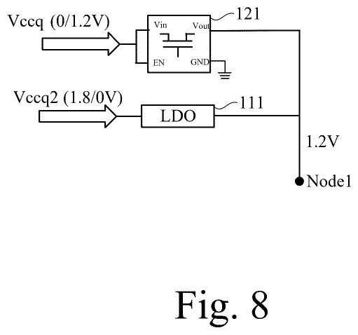

FIG. 8 is a first schematic diagram of a voltage control circuit provided in an example of the present disclosure. In some examples, as shown in FIG. 8, the first voltage control sub-circuit includes a first voltage regulator 111. The input terminal of the first voltage regulator 111 is coupled to the first power supply pin Vccq2, and the output terminal of the first voltage regulator 111 is coupled to the first voltage node Node1. The first voltage regulator 111 is configured to convert the first power supply voltage into a first target voltage in response to the first voltage signal being a first power supply voltage.

In this example, the first power supply voltage is different from the first target voltage. In general, the first power supply voltage is greater than the first target voltage. For example, as shown in FIG. 8, the first power supply voltage is 1.8V and the first target voltage is 1.2V. The first voltage regulator may be any voltage regulator commonly used in the art, which is not limited in the present disclosure. For example, the first voltage regulator may be a low dropout linear regulator (LDO).

In some examples, as shown in FIG. 8, the second voltage control sub-circuit includes a first switch 121. The first terminal Vin and the control terminal EN of the first switch 121 are coupled to the second power supply pin Vccq, and the second terminal Vout of the first switch 121 is coupled to the first voltage node Node1. The first switch 121 is configured to be in a turned-off state in response to the second voltage signal being a first idle voltage, so as to disconnect the first current pathway.

In this example, the control terminal EN of the first switch is coupled to the second power supply pin Vccq, which indicates that the first control signal En_1 is a second voltage signal. When the second voltage signal is a first idle voltage (e.g., ground voltage), the first switch is in a turned-off state, so that the second power supply pin is disconnected with the first voltage node, thus effectively preventing the current at the first voltage node from flowing back to the second power supply pin Vccq without generating an additional voltage drop.

The first switch 121 is a load switch, the basic principle of which is to turn on and off the power by controlling pins. As shown in FIG. 4, a load switch typically includes four pins, e.g., a control pin EN, an input voltage pin Vin, an output voltage pin Vout, and a ground pin GND, wherein the ground pin GND is grounded. Of course, some load switches may not have a ground pin GND. For example, the first switch is an N-channel field-effect transistor, shortened as an NMOS transistor. When the control terminal of the NMOS transistor receives a low voltage less than a threshold voltage, the NMOS transistor is in a turned-off state. In this example, the threshold voltage of the NMOS transistor is greater than the first idle voltage.

In first power supply scheme, the first power supply pin receives a first power supply voltage (e.g., 1.8V), and the first voltage regulator converts the first power supply voltage into a first target voltage (e.g., 1.2V); at the same time, the second power supply pin receives a first idle voltage (e.g., 0V), and the first switch is in a turned-off state in response to the first idle voltage, so that the first voltage node has a first target voltage of 1.2V.

In some examples, the first switch 121 is configured to be in a turned-on state in response to the second voltage signal being a second power supply voltage, to output the second power supply voltage as a first target voltage. The first voltage regulator 111 is configured to stop operation in response to the first voltage signal being a second idle voltage, so as to disconnect the second current pathway, wherein the second idle voltage is beyond the input range of the first voltage regulator.

Continuing to refer to FIG. 8, the second voltage control sub-circuit provided in this example is applicable to the case where the second power supply voltage is equal to a first target voltage. For example, in FIG. 8, the second power supply voltage and the first target voltage are both 1.2V. When the second power supply pin Vccq receives a second power supply voltage (e.g., 1.2V), the first switch 121 is turned on and outputs the second power supply voltage as a first target voltage.

The selection of the first voltage regulator 111 satisfies the requirement that the second idle voltage is beyond the input voltage range of the first voltage regulator, that is, when the input terminal of the first voltage regulator is a second idle voltage, the first voltage regulator cannot operate. At this point, there is no current between the input and output terminal of the first voltage regulator, and the second current pathway may be considered as disconnected. In this example, the second idle voltage is a ground voltage of 0V, and the first voltage regulator does not operate, which will not affect the voltage of the first voltage node. In this example, the second control signal En_2 may be considered as a first voltage signal, which may control the first voltage regulator to stop operation and disconnect the second current pathway.

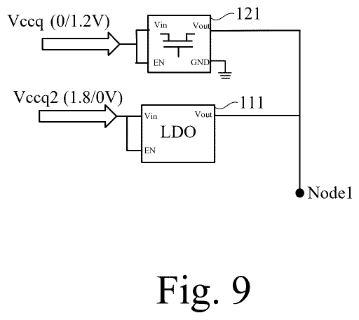

In some examples, as shown in FIG. 9, the first voltage regulator is an LDO 111 with an enable terminal EN, which may control the LDO 111 to operate or stop operation. For example, the enable terminal of LDO 111 is active at a high level. The enable terminal of LDO 111 operates when receiving a high level (e.g., greater than 1.2V) and stops operation when receiving a low level (e.g., 0V). As shown in FIG. 9, the enable terminal EN of LDO 111 is directly connected to its input terminal, or in other examples, the enable terminal EN of LDO 111 is connected to its input terminal after being connected in series with a resistor. As such, when the first power supply pin Vccq2 receives a first power supply voltage, LDO 111 operates; and when the first power supply pin receives a second idle voltage, LDO 111 stops operation to disconnect the second current pathway. In practical applications, either one of the two LDOs may be selected as needed.

In summary, in the second power supply scheme, the second power supply pin Vccq receives a second power supply voltage (e.g., 1.2V), and the first switch is in a turned-on state in response to the second power supply voltage, to output a first target voltage (e.g., 1.2V) equal to the second power supply voltage. The input terminal of the first voltage regulator receives a second idle voltage (e.g., 0V) and stops operation.

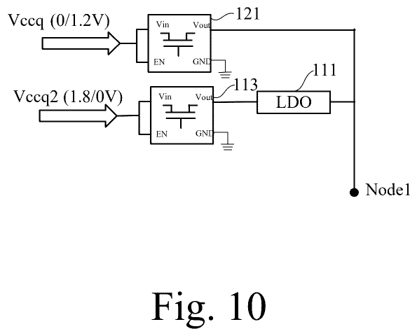

FIG. 10 is a third schematic diagram of a voltage control circuit provided in an example of the present disclosure. Compared to the first voltage control sub-circuit shown in FIG. 8, the first voltage control sub-circuit shown in FIG. 10 further includes a fourth switch 113. The first terminal Vin and control terminal EN of the fourth switch 113 are coupled to the first power supply pin Vccq2, and the second terminal Vout of the fourth switch 113 is coupled to the first voltage regulator 111. The fourth switch 113 is configured to be in a turned-on state in response to the first voltage signal being a first power supply voltage (e.g., 1.8V), so that the first voltage regulator 111 receives the first power supply voltage; and configured to be in a turned-off state in response to the first voltage signal being a second idle voltage (e.g., 0V), so as to disconnect the second current pathway. For example, the fourth switch 113 is an NMOS transistor.

In the case that the fourth switch 113 is included, the present disclosure has no limitation on whether the first voltage regulator needs to meet the requirement that the second idle voltage is not within its input range, and thus the selection range of the first voltage regulator may be expanded. However, if the fourth switch 113 is adopted and also the first voltage regulator satisfies that the second idle voltage is not within its input range, the second current pathway may be disconnected more reliably. It should be understood that this example illustrates the case where the second control signal En_2 is the first voltage signal.

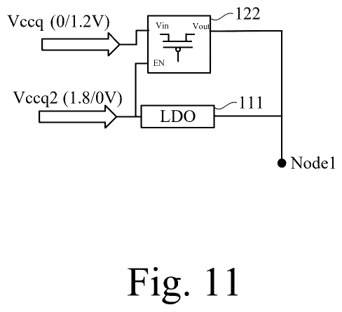

FIG. 11 is a fourth schematic diagram of a voltage control circuit provided in an example of the present disclosure. As shown in FIG. 11, in some examples, the first voltage control sub-circuit includes a first voltage regulator 111, and the input and output terminals of the first voltage regulator 111 are coupled to the first power supply pin Vccq2 and the first voltage node Node1, respectively. The second voltage control sub-circuit includes a fifth switch 122, and the first terminal Vin and the second terminal Vout of the fifth switch 122 are coupled to the second power supply pin Vccq and the first voltage node Node1, respectively. The control terminal EN of the fifth switch 122 is coupled to the first power supply pin Vccq2. The fifth switch 122 is configured to be turned off in response to the first voltage signal being a first power supply voltage and turned on in response to the first voltage signal being a second idle voltage. For example, the fifth switch 122 is a PMOS transistor.

This example illustrates the case where the first control signal En_1 is the first voltage signal and the second control signal En_2 is also the first voltage signal. In practical operations, in the first power supply scheme, when the first power supply pin Vccq2 receives a first power supply voltage (e.g., 1.8V), the first voltage regulator 111 converts the first power supply voltage into a first target voltage (e.g., 1.2V), and the fifth switch 122 is in a turned-off state in response to the first power supply voltage, so as to disconnect the first current pathway.

In the second power supply scheme, when the second power supply pin Vccq receives a second power supply voltage (e.g., 1.2V), the first power supply pin Vccq2 receives a second idle voltage (e.g., 0V), the fifth switch 122 is in a turned-on state in response to the second idle voltage, to output a first target voltage equal to the second power supply voltage. Meanwhile, the first voltage regulator 111 disconnects the second current pathway in response to the second idle voltage not being within its input range.

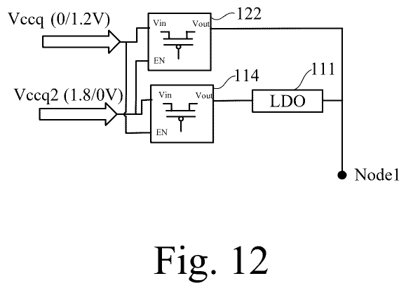

FIG. 12 is a fifth schematic diagram of a voltage control circuit provided in an example of the present disclosure. Compared to FIG. 11, the first voltage control sub-circuit in the voltage control circuit further includes a sixth switch 114. The first terminal Vin and the second terminal Vout of the sixth switch 114 are coupled to the first power supply pin Vccq2 and the first voltage regulator 111, respectively, and the control terminal EN of the sixth switch 114 is coupled to the second power supply pin Vccq. The sixth switch 114 is configured to be in a turned-on state in response to the second voltage signal being a first idle voltage, to turn on the first voltage regulator 111 and the first power supply pin Vccq2, so that the first voltage regulator 111 receives a first power supply voltage; and configured to be in a turned-off state in response to the second voltage signal being a second power supply voltage, so as to disconnect the second current pathway. For example, the sixth switch 114 is a PMOS transistor.

In the case that the sixth switch 114 is included, the present disclosure has no limitation on whether the first voltage regulator needs to meet the requirement that the second idle voltage is not within its input range, and thus the selection range of the first voltage regulator may be expanded. However, if the sixth switch 114 is adopted and also the first voltage regulator satisfies that the second idle voltage is not within its input range, the second current pathway may be disconnected more reliably. It should be understood that this example illustrates the case where the first control signal En_1 is the second voltage signal and the second control signal En_1 is the first voltage signal.

In summary, the first voltage control sub-circuit and the second voltage control sub-circuit provided in examples of the present disclosure may support two power supply schemes, and may provide a first target voltage to a first device under both power supply schemes, thereby improving the compatibility and competitiveness of products.

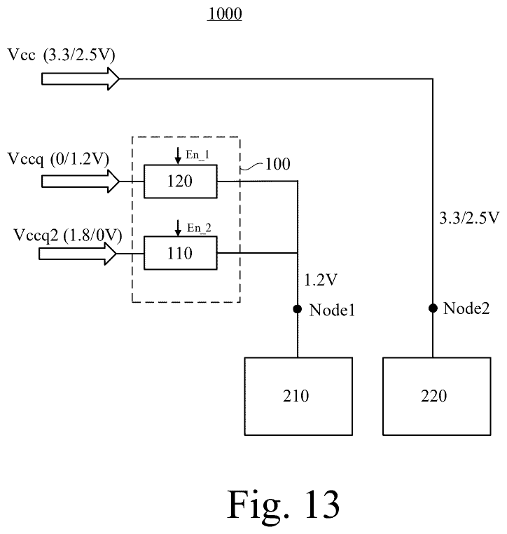

FIG. 13 is a second schematic diagram of a memory system comprising a voltage control circuit provided in an example of the present disclosure. As shown in FIG. 13, the memory system 1000 further includes a third power supply pin Vcc and a second device 220. The third power supply pin Vcc receives a third voltage signal, which includes at least one of a third power supply voltage or a fourth power supply voltage. For example, in the first power supply scheme, the third voltage signal is a third power supply voltage (e.g., 3.3V); and in the second power supply scheme, the third voltage signal is a fourth power supply voltage (e.g., 2.5V). In other examples, the third voltage signal may switch between the third power supply voltage and the fourth power supply voltage.

In some examples, as shown in FIG. 13, if the second device 220 may support operation at both the third power supply voltage and the fourth power supply voltage, the third power supply pin Vcc may be coupled to the second device 220 directly through the second voltage node Node2.

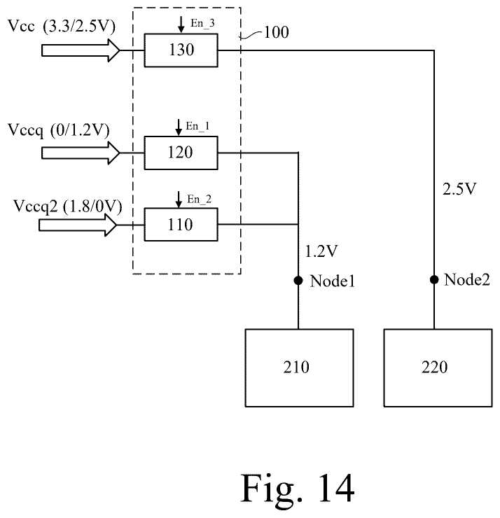

In other examples, if the second device only supports operation at one of the power supply voltages, the voltage control circuit further needs to regulate the power supply voltage received by the third power supply pin. FIG. 14 is a third schematic diagram of a memory system comprising a voltage control circuit provided in an example of the present disclosure. As shown in FIG. 14, the voltage control circuit further includes a third voltage control sub-circuit 130 coupled to the third power supply pin Vcc and the second voltage node Node2. The third voltage control sub-circuit 130 is configured to output a second target voltage in response to the third control signal En_3 being at the first level and the third voltage signal received by the third power supply pin Vcc being a third power supply voltage, and/or configured to output a second target voltage in response to the third control signal En_3 being at a second level and the third voltage signal being a fourth power supply voltage. The second device 220 is coupled to the second voltage node Node2, and the second target voltage is the operating voltage of the second device 220.

The third voltage control sub-circuit in this example may unify the two cases of the third power supply voltage and the fourth power supply voltage into the second target voltage, so that it may provide the second target voltage to the second device regardless of whether the application platform provides the third power supply voltage or the fourth power supply voltage, which may improve the platform compatibility and competitiveness of the memory system.

In some examples, the third control signal En_3 may be provided internally in a memory system. For example, when the first power supply scheme is determined to be provided by the application platform, the controller in the memory system may set the third control signal EN_3 to a first level, and when the second power supply scheme is determined to be provided by the application platform, the controller may set the third control signal EN_4 to a second level.

In other examples, the third control signal En_3 may be provided by an application platform. For example, the third voltage control sub-circuit 130 is coupled to the second power supply pin Vccq, and the third control signal En_3 is a second voltage signal, wherein the third control signal En_3 being at the first level refers to the second voltage signal being a first idle voltage (e.g., 0V), and the third control signal En_3 being at the second level refers to the second voltage signal being a second power supply voltage (e.g., 1.2V).

In practical operations, in the first power supply scheme, the application platform provides a first idle voltage to the second power supply pin Vccq and a third power supply voltage (e.g., 3.3V) to the third power supply pin Vcc simultaneously. The third voltage control sub-circuit 130 obtains a second target voltage based on the third power supply voltage in response to the first idle voltage. In the second power supply scheme, the application platform provides a second power supply voltage (e.g., 1.2V) to the second power supply pin Vccq and a fourth power supply voltage (e.g., 2.5V) to the third power supply pin Vcc simultaneously. The third voltage control sub-circuit 130 obtains the second target voltage based on the fourth power supply voltage in response to the second power supply voltage.

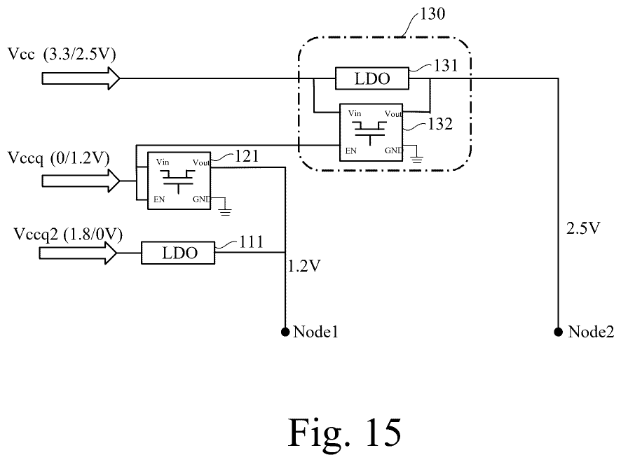

FIG. 15 is a sixth schematic diagram of a voltage control circuit provided in an example of the present disclosure. In some examples, as shown in FIG. 15, the third voltage control sub-circuit 130 includes a second voltage regulator 131 and a second switch 132. The input terminal of the second voltage regulator 131 is coupled to the third power supply pin Vcc, and the output terminal of the second voltage regulator 131 is coupled to the second voltage node Node2. The second voltage regulator 131 is configured to convert the third power supply voltage into a second target voltage in response to the third voltage signal being the third power supply voltage. The two terminals Vin and Vout of the second switch 132 are connected in parallel to the two terminals of the second voltage regulator 131. The control terminal EN of the second switch 132 is coupled to the second power supply pin Vccq. The second switch 132 is configured to be in a turned-off state in response to the second voltage signal being a first idle voltage, and/or configured to be in a turned-on state in response to the second voltage signal being a second power supply voltage, to output the fourth power supply voltage as the second target voltage.

At least one of the third power supply voltage and the fourth power supply voltage is different from the second target voltage. The third voltage control sub-circuit 130 provided in this example is applicable to the case where the second target voltage is equal to a fourth power supply voltage. For example, as shown in FIG. 15, the second target voltage is equal to the fourth power supply voltage and is equal to 2.5V; and the third power supply voltage is different from the second target voltage, for example, the third power supply voltage is 3.3V. This example illustrates the case where the third control signal En_3 is the second voltage signal.

As shown in FIG. 15, in the first power supply scheme, the second power supply pin Vccq receives a first idle voltage (e.g., 0V), and the third power supply pin Vcc receives the third power supply voltage. At this point, the second switch 132 is turned off by the control of the first idle voltage, and the second voltage regulator 131 operates to convert the third power supply voltage into a second target voltage. For example, if the third power supply voltage is greater than the second target voltage, the second voltage regulator reduces the third power supply voltage to the second target voltage.

In the second power supply scheme, the second power supply pin Vccq receives a second power supply voltage (e.g., 1.2V), and the third power supply pin Vcc receives a fourth power supply voltage. At this point, the second switch 132 is turned on by the control of the second power supply voltage to short-circuit the second voltage regulator 131, so that the fourth power supply voltage is transmitted to the second voltage node Node2 through the second switch 132 as the second target voltage.

For example, the second switch 132 is an NMOS transistor, and the threshold voltage of the NMOS transistor is less than or equal to the second power supply voltage and greater than the first idle voltage. The NMOS transistor is turned on in response to the second power supply voltage being greater than or equal to its threshold voltage, and turned off in response to the first idle voltage being less than its threshold voltage. The second voltage regulator 131 is an LDO, and the third power supply voltage is within the input range of the LDO, and when the LDO satisfies that the input voltage is the third power supply voltage, the output voltage is the second target voltage.

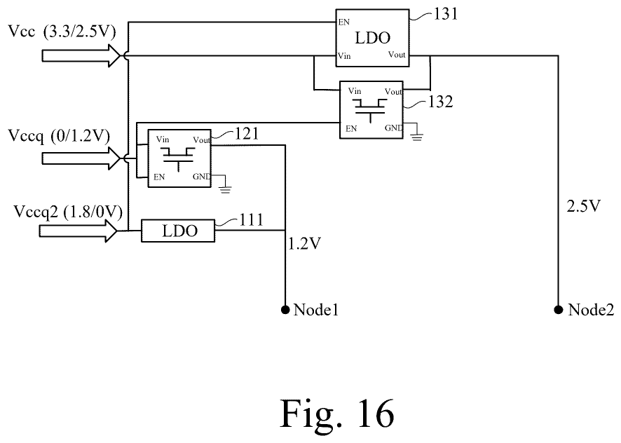

In some examples, as shown in FIG. 16, the second voltage regulator is an LDO 131 with an enable terminal EN. For example, the enable terminal EN of LDO 131 is active at a high level, and operates when the enable terminal EN of LDO 131 receives a high level (e.g., greater than 1.2V) and stops operation when receiving a low level (e.g., 0V). As shown in FIG. 16, the enable terminal EN of LDO 131 is connected to the first power supply pin Vccq2; or in other examples, the enable terminal EN of LDO 131 is connected to the first power supply pin Vccq2 after being connected in series with a resistor. As such, in the first power supply scheme, when the application platform synchronously provides a first power supply voltage to the first power supply pin Vccq2, a first idle voltage to the second power supply pin Vccq and a third power supply voltage to the third power supply pin Vcc, the second switch 132 is turned off, and the LDO 131 operates to convert the third power supply voltage into a second target voltage. In the second power supply scheme, when the application platform synchronously provides a second idle voltage to the first power supply pin Vccq2, a second power supply voltage to the second power supply pin Vccq and a fourth power supply voltage to the fourth power supply pin Vcc, the LDO 131 stops operation, and the second switch 132 is turned on to output the fourth power supply voltage to the second voltage node Node2 as the second target voltage. When the first power supply pin receives the second idle voltage, LDO 111 stops operation to disconnect the second current pathway. Compared to the LDO in FIG. 15, which is short-circuited by the second switch 132 and does not operate in the second power supply scheme, this LDO with an enable terminal may stop operation in the second power supply scheme, more reliably ensuring that the pathway where the LDO is located is not involved in current transmission, so that the second target voltage is equal to the fourth power supply voltage. In practical applications, either one of the two LDOs may be selected as needed.

Another implementation of the third control signal En_3 provided by an application platform is that: the third voltage control sub-circuit 130 is coupled to the first power supply pin Vccq2, and the third control signal En_3 is a first voltage signal. The third control signal En_3 being at a first level refers to the first voltage signal being a first power supply voltage (e.g., 1.8V), and the third control signal being at a second level refers to the first voltage signal being a second idle voltage (e.g., 0V).

In practical operations, in the first power supply scheme, the application platform provides a first power supply voltage to the first power supply pin Vccq2 and a third power supply voltage (e.g., 3.3V) to the third power supply pin Vcc simultaneously. The third voltage control sub-circuit 130 obtains a second target voltage based on the third power supply voltage in response to the first power supply voltage. In the second power supply scheme, the application platform provides a second idle voltage (e.g., 0V) to the first power supply pin Vccq2 and a fourth power supply voltage (e.g., 2.5V) to the third power supply pin Vcc simultaneously. The third voltage control sub-circuit 130 obtains a second target voltage based on the fourth power supply voltage in response to the second power supply voltage.

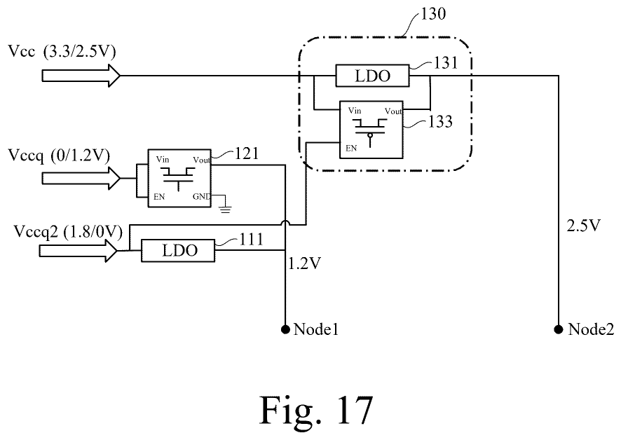

FIG. 17 is an eighth schematic diagram of a voltage control circuit provided in an example of the present disclosure. In some examples, as shown in FIG. 17, the third voltage control sub-circuit 130 includes a second voltage regulator 131 and a third switch 133. The input terminal of the second voltage regulator 131 is coupled to the third power supply pin Vcc, and the output terminal of the second voltage regulator 131 is coupled to the second voltage node Node2. The second voltage regulator 131 is configured to convert the third power supply voltage into a second target voltage in response to the third voltage signal being the third power supply voltage. The two terminals Vin and Vout of the third switch 133 are connected in parallel to the two terminals of the second voltage regulator 131. The control terminal EN of the third switch 133 is coupled to the first power supply pin Vccq2. The third switch 133 is configured to be in a turned-off state in response to the first voltage signal being a first power supply voltage, and/or configured to be in a turned-on state in response to the first voltage signal being a second idle voltage to output a fourth power supply voltage as the second target voltage.

This example is also applicable to the case where the fourth power supply voltage is equal to the second target voltage. For example, the second switch is a PMOS transistor. The PMOS transistor is turned off in response to the first power supply voltage being greater than its threshold voltage, and turned on in response to the second idle voltage being less than or equal to its threshold voltage.

As shown in FIG. 17, in the first power supply scheme, the first power supply pin Vccq2 receives a first power supply voltage (e.g., 1.8V), and the third power supply pin Vcc receives a third power supply voltage. At this point, the third switch 133 is disconnected by the control of the first power supply voltage, and the second voltage regulator 131 operates to convert the third power supply voltage into a second target voltage. In the second power supply scheme, the first power supply pin Vccq2 receives a second idle voltage (e.g., 0V), and the third power supply pin Vcc receives a fourth power supply voltage. At this point, the third switch 133 is turned on by the control of the second idle voltage, to short-circuit the second voltage regulator 131, so that the fourth power supply voltage is transmitted to the second voltage node Node2 through the third switch 133.

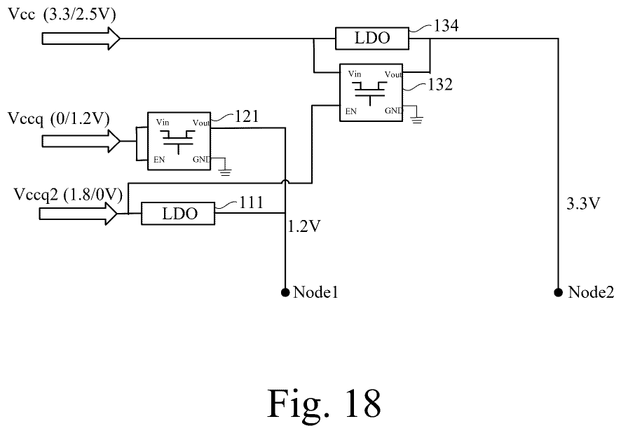

The third voltage control sub-circuit shown in FIGS. 15 to 17 is applicable to the case where the second target voltage is equal to the fourth power supply voltage. In some examples, the second target voltage may also be equal to the third power supply voltage. FIG. 18 is a ninth schematic diagram of a voltage control circuit provided in an example of the present disclosure. As shown in FIG. 18, the third voltage control sub-circuit includes a fourth voltage regulator 134 and a second switch 132. The input terminal of the fourth voltage regulator 134 is coupled to the third power supply pin Vcc, and the output terminal of the fourth voltage regulator 134 is coupled to the second voltage node Node2. The fourth voltage regulator 134 is configured to convert the fourth power supply voltage into a second target voltage in response to a third voltage signal. The two terminals of the second switch 132 are connected in parallel to the two terminals of the fourth voltage regulator 134. The control terminal of the second switch 132 is coupled to the second power supply pin. The second switch 132 is configured to be in a turned-on state in response to the first voltage signal being the first power supply voltage, to output the third power supply voltage as the second target voltage; and/or configured to be in a turned-off state in response to the first voltage signal being a second idle voltage.

As shown in FIG. 18, the second target voltage is equal to the third power supply voltage and is equal to 3.3V. The fourth power supply voltage is different from the second target voltage, for example, the fourth power supply voltage is 2.5V. This example illustrates the case where the third control signal En_3 is the first voltage signal.

As shown in FIG. 18, in the first power supply scheme, the first power supply pin Vccq2 receives a first power supply voltage (e.g., 1.8V), and the third power supply pin Vcc receives a third power supply voltage. At this point, the second switch 132 is turned on by the control of the first power supply voltage, to short-circuit the fourth voltage regulator 134, so that the third power supply voltage is transmitted to the second voltage node Node2 through the second switch 132 as the second target voltage. In the second power supply scheme, the first power supply pin Vccq2 receives a second idle voltage (e.g., 0V), and the third power supply pin Vcc receives a fourth power supply voltage. At this point, the second switch 132 is turned off by the control of the second idle voltage, and the fourth voltage regulator 134 operates to convert the fourth power supply voltage into a second target voltage. For example, if the fourth power supply voltage is lower than the second target voltage, the fourth voltage regulator 134 boosts the fourth power supply voltage to the second target voltage. The fourth voltage regulator 134 may be any voltage regulator commonly used in the art that may boost voltage.

It should be understood that, in another example, in the case where the second target voltage is equal to the third power supply voltage, the third control signal En_3 may also be a second voltage signal. At this point, the second switch 132 is replaced with the third switch 133 (PMOS transistor), and the control terminal EN of the third switch is connected to the second power supply pin Vccq.

In summary, the third voltage control sub-circuit provided in an example of the present disclosure may support two power supply schemes, and may provide a second target voltage to a second device under both power supply schemes, thereby improving the compatibility and competitiveness of products.

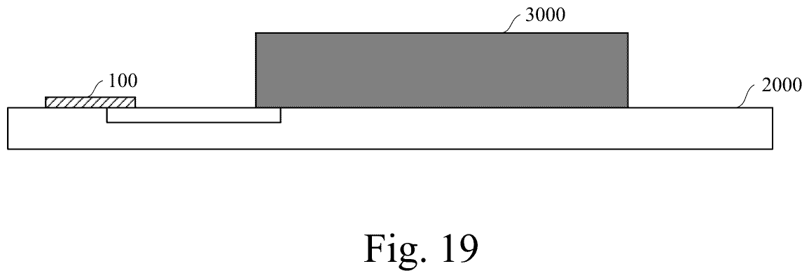

FIG. 19 is a fourth schematic diagram of a memory system comprising a voltage control circuit provided in an example of the present disclosure. In some examples, as shown in FIG. 19, the memory system further includes a packaging substrate 2000 and a die 3000 located on the packaging substrate 2000, wherein the voltage control circuit 100 is located on the packaging substrate 2000.

In the UFS product shown in FIG. 5, all four voltage controllers LDO are disposed inside the die. For example, all four voltage controllers LDO are disposed inside the memory controller die. Due to Vccq2=1.8V, which is much higher than the operating voltage 0.8V of the controller, this excessive voltage difference causes the LDO voltage drop to generate a large amount of heat, resulting in severe heating of the die. In this example, two voltage regulators (the first voltage regulator and the second voltage regulator (or the fourth voltage regulator)) are disposed on the packaging substrate 2000 outside the die to facilitate heat dissipation, thereby significantly reducing the heat dissipation requirements of the memory system and ensuring reliability.

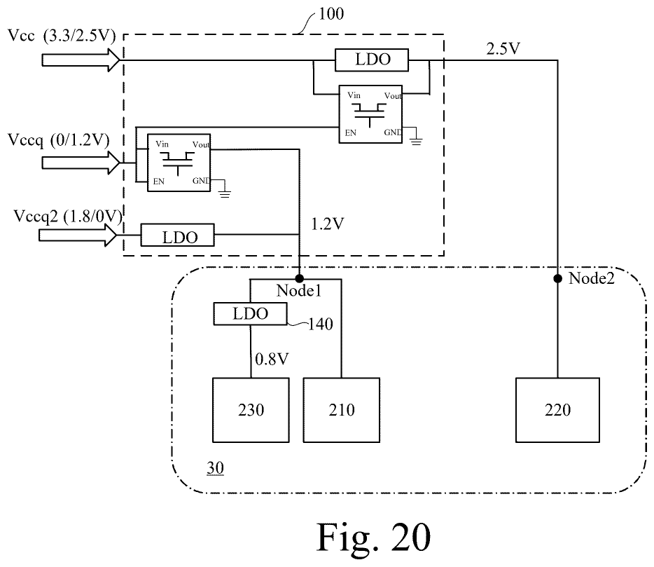

FIG. 20 is a fifth schematic diagram of a memory system comprising a voltage control circuit provided in an example of the present disclosure. In some examples, the first device 210 and the second device 220 are located inside the die 3000. The die 3000 further includes a third voltage regulator 140 and a third device 230. The third voltage regulator 140 is coupled to the first voltage node Node1 and configured to convert a first target voltage into a third target voltage. The third device 230 is coupled to the third voltage regulator 140. The operating voltage of the third device 230 is the third target voltage.

It should be understood that the operating voltage of some devices of the die may be different from the first target voltage and the second target voltage, and it is necessary to set the third voltage regulator 140 to further convert the first target voltage into the third target voltage. In an example, the third target voltage is lower than the first target voltage. For example, in FIG. 20, the third target voltage is 0.8V, which is lower than the first target voltage of 1.2V. Compared to directly converting a first power supply voltage or a second power supply voltage into the third target voltage, in this example, the first power supply voltage is first converted into the first target voltage, and then further converted into the third target voltage, which may reduce the voltage difference at each conversion operation, thereby reducing the heat dissipation of the voltage regulator and ensuring reliability.

In some examples, the third voltage regulator 140 is an LDO.

In some examples, a memory controller and a memory device may be integrated on one die. In other examples, the memory controller and memory device may also be separately formed on different dies, for example, formed as a memory controller die and one or more memory dies. The memory controller includes a front-end I/O that communicates with an external host, a memory device I/O that communicates with a memory device, and a controller core. The memory device includes a memory device I/O that communicates with the memory controller, a memory cell array, and a peripheral circuit configured to control the memory cell array in addition to the memory device I/O.

For example, a memory device includes, but is not limited to, NAND Flash Memory Devices, Vertical NAND Flash Memory, NOR Flash Memory, Dynamic Random Access Memory (DRAM), Ferroelectric Random Access Memory (FRAM), Magnetoresistive Random Access Memory (MRAM), Phase Change Random Access Memory (PCRAM), Resistive Random Access Memory (RRAM), Nano Random Access Memory (NRAM), etc. The memory device may be any of the memory devices described in any of the examples in FIGS. 1A to 6.

The memory controller may be coupled to the memory device and the host, and configured to control the memory device. The memory controller may be any of the memory controllers described in any of the examples in FIGS. 1A to 6.

In some examples, the memory controller and one or more memory devices may be included in the same package, such as a UFS package or eMMC package. In this package, the memory controller die and the memory die may be arranged in parallel on the package substrate 2000, or stacked on the package substrate 2000. For example, the voltage control circuit is separately provided on the packaging substrate 2000.

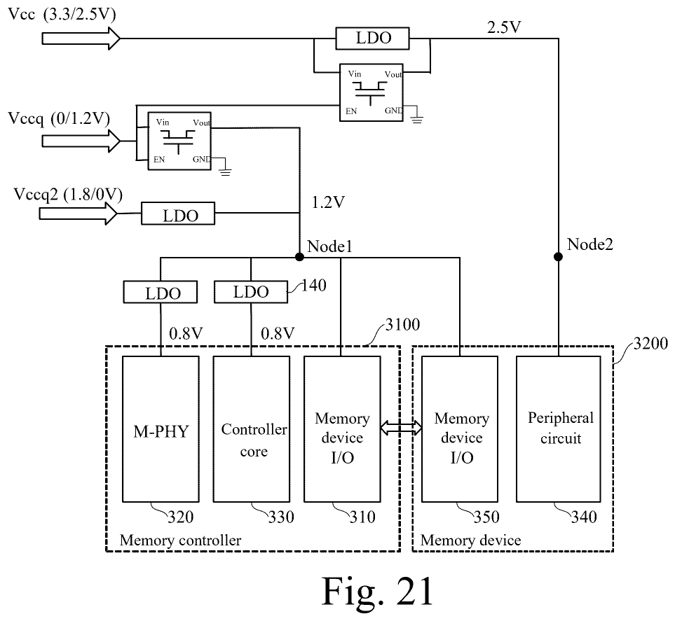

The present disclosure takes UFS products as an example to illustrate the disclosed solution, but it does not limit the application of the disclosed technical solution only to UFS products. FIG. 21 is a schematic diagram of a Universal Flash Storage provided in an example of the present disclosure. In some examples, as shown in FIG. 21, the Universal Flash Storage includes a memory controller 3100 and a memory device 3200, and the memory controller 3100 is coupled to the memory device 3200. The first device 210, the second device 220 and the third device 230 in the above examples may be any device in at least one of the memory controller or memory device.

In some examples, the first device 210 includes a memory device input/output (I/O) 310 in the memory controller 3100 and a memory device input/output (I/O) 350 in the memory device 3200, which are both coupled to the first voltage node Node1. For example, the operating voltage of the two memory devices with input/output 310 and 350 is 1.2V. For example, both the memory devices input/output 310 and 350 are flash memory input/output devices that communicate based on ONFI protocol or NVMe protocol. For example, the memory device input/output 310, 350 in this example may correspond to the memory device I/O 93, 95 in FIGS. 5 and 6.

In some examples, the second device 220 includes a physical layer (M-PHY) 320, a controller core 330, and is coupled to the third voltage regulator 140. In one example, as shown in FIG. 21, the physical layer 320 and the controller core 330 may be coupled to different third voltage regulators 140. In another example, the physical layer and controller core may also be coupled to the same third voltage regulator 140. For example, the physical layer 320 and controller core 330 in this example may be the M-PHY 91 and controller core 92 in FIGS. 5 and 6.

In some examples, the peripheral circuit of the memory device supports operating at the third and fourth power supply voltages, and at this point, the voltage control circuit may not include the third voltage control sub-circuit 130. In some other examples, the peripheral circuit of the memory device only supports operating at one power supply voltage. At this point, as shown in FIG. 21, the voltage control circuit further includes the third voltage control sub-circuit. The peripheral circuit 340 in the memory device except for the input/output 350 is coupled to the third voltage control sub-circuit through the second voltage node Node2. For example, the peripheral circuit in this example may be the peripheral circuit 96 in FIGS. 5 and 6. For example, the memory device may be a flash memory.

In some examples, UFS products may be integrated into an application platform, including but not limited to, a mobile electronic product such as a smart phone, a tablet, a computer, etc. The application platform communicates with the UFS products through UFS protocol. The Universal Flash Storage provided in this example may simultaneously support multiple UFS standards with different schemes. For example, both UFS2.2 and UFS3.1 standards may be supported simultaneously.

Compared to the UFS product in FIG. 5, the UFS product in this example has two voltage regulators provided on the packaging substrate 2000, which may significantly reduce the heat dissipation requirements of the product and ensure reliability. Compared to the UFS product in FIG. 6, when the UFS product in this example uses the same power supply scheme, only two of the third voltage regulators inside the die operate, which is the same as the UFS product in FIG. 6, and the number of voltage regulators in use is not increased. Therefore, the heating conditions are basically the same.

In addition, when the memory controller used in the memory system is a newer generation UFS product shown in FIG. 6 (such as a product that supports the UFS3.1 standard), even if the memory system is applied to an application platform that supplies power to a previous generation UFS product shown in FIG. 5 (such as a product that supports the UFS2.2 standard), the host may switch speed to HS_Gear4 and overclock into the newer generation UFS product for use, without protocol or compatibility restrictions, which means that such a memory system may support the UFS2.1 standard and also overclock into UFS3.1 for use, thereby improving the competitiveness of products.

In summary, the memory system provided in this example adds LDO into the Vccq2 circuit, resulting in a decrease in the Vccq2 voltage from 1.8V to 1.2V and an integration with the Vccq circuit. Adding an LDO that results in a decrease from 3.3V to 2.5V at the Vcc terminal will stabilize to 2.5V regardless of whether the voltage at the Vcc terminal is 3.3V or 2.5V. As such, by adding a small number of devices, it is possible to be compatible with two standards, which greatly saves research and development costs, and greatly improves market applicability, customer acceptance, and competitiveness.

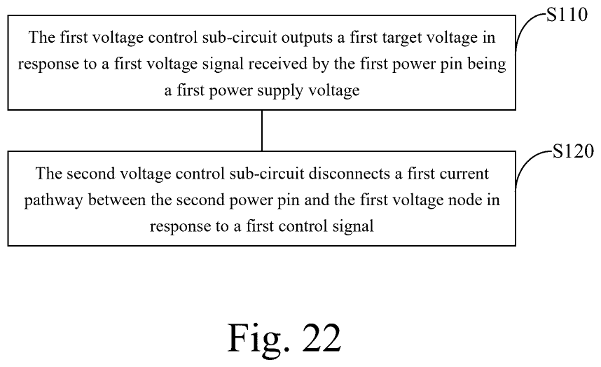

Examples of the present disclosure also provide a voltage control method applied to a memory system. The memory system includes a first voltage control sub-circuit coupled to a first power supply pin and a first voltage node, and a second voltage control sub-circuit coupled to a second power supply pin and the first voltage node. FIGS. 22, 23, and 24 are flow diagrams of various voltage control methods provided in examples of the present disclosure. In some examples, as shown in FIG. 22, the voltage control method includes:
S110: the first voltage control sub-circuit outputs a first target voltage in response to a first voltage signal received by the first power supply pin being a first power supply voltage; and
S120: the second voltage control sub-circuit disconnects a first current pathway between the second power supply pin and the first voltage node in response to a first control signal.

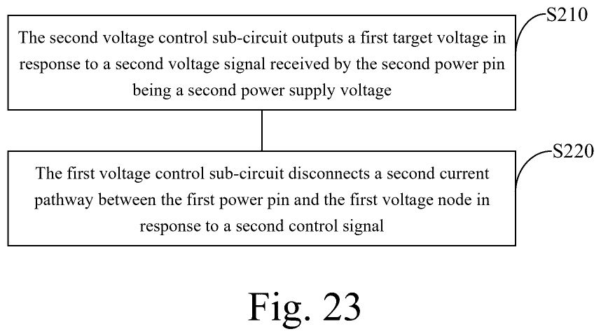

In some other examples, as shown in FIG. 23, the voltage control method includes:
S210: the second voltage control sub-circuit outputs a first target voltage in response to a second voltage signal received by the second power supply pin being a second power supply voltage; and
S220: the first voltage control sub-circuit disconnects a second current pathway between the first power supply pin and the first voltage node in response to a second control signal.

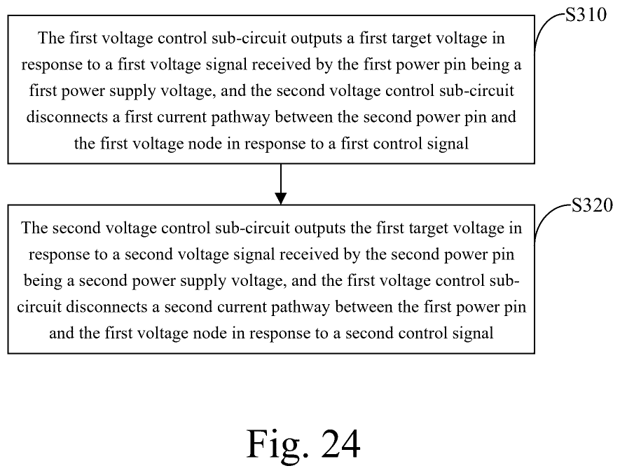

In some other examples, as shown in FIG. 24, the voltage control method includes:
S310: the first voltage control sub-circuit outputs a first target voltage in response to a first voltage signal received by the first power supply pin being a first power supply voltage, and the second voltage control sub-circuit disconnects a first current pathway between the second power supply pin and the first voltage node in response to a first control signal; and
S320: the second voltage control sub-circuit outputs the first target voltage in response to a second voltage signal received by the second power supply pin being a second power supply voltage, and the first voltage control sub-circuit disconnects a second current pathway between the first power supply pin and the first voltage node in response to a second control signal.

The voltage control method provided in examples of the present disclosure regulates both the first power supply voltage and the second power supply voltage to the first target voltage. Thus, when a memory system including a voltage control circuit is integrated into an application platform, regardless of whether the power supply scheme of the application platform provides the first power supply voltage to the first power supply pin or the second power supply voltage to the second power supply pin, the voltage control circuit in the memory system may provide the first target voltage to the device. As such, a memory system may support two power supply schemes simultaneously without providing two memory systems for two power supply schemes, thereby reducing research and development investment, saving research and development costs, and improving the platform compatibility and competitiveness of products.

In some examples, the first control signal is the second voltage signal. The second voltage control sub-circuit in S120 or S310 disconnecting the first current pathway between the second power supply pin and the first voltage node in response to the first control signal comprises that: the second voltage control sub-circuit disconnects the first current pathway in response to the second voltage signal being a first idle voltage.

In some examples, the second control signal is the first voltage signal. The first voltage control sub-circuit in S220 or S320 disconnecting the second current pathway between the first power supply pin and the first voltage node in response to the second control signal comprises that:
the first voltage control sub-circuit disconnects the second current pathway in response to the first voltage signal being a second idle voltage.

In some examples, the first voltage control sub-circuit includes a first voltage regulator. The input terminal of the first voltage regulator is coupled to the first power supply pin and the output terminal of the first voltage regulator is coupled to the first voltage node. The second voltage control sub-circuit includes a first switch. The first terminal and the control terminal of the first switch are coupled to the second power supply pin, and the second terminal of the first switch is coupled to the first voltage node. The first voltage control sub-circuit in S110 or S310 outputting the first target voltage in response to the first voltage signal received by the first power supply pin being the first power supply voltage comprises that: the first voltage regulator receives the first power supply voltage and converts the first power supply voltage into the first target voltage.

The second voltage control sub-circuit in S210 or S310 disconnecting the first current pathway in response to the second voltage signal being the first idle voltage comprises that: the first switch is in a turned-off state in response to the first idle voltage to disconnect the first current pathway.

In some examples, the second voltage control sub-circuit in S210 or S320 outputting the first target voltage in response to the second voltage signal received by the second power supply pin being the second power supply voltage comprises that: the first switch is in a turned-on state in response to the second power supply voltage to output the second power supply voltage as the first target voltage.

The first voltage control sub-circuit in S220 or S320 disconnecting the second current pathway in response to the first voltage signal being the second idle voltage comprises that: the first voltage regulator stops operation in response to the second idle voltage to disconnect the second current pathway, wherein the second idle voltage is beyond the input range of the first voltage regulator.

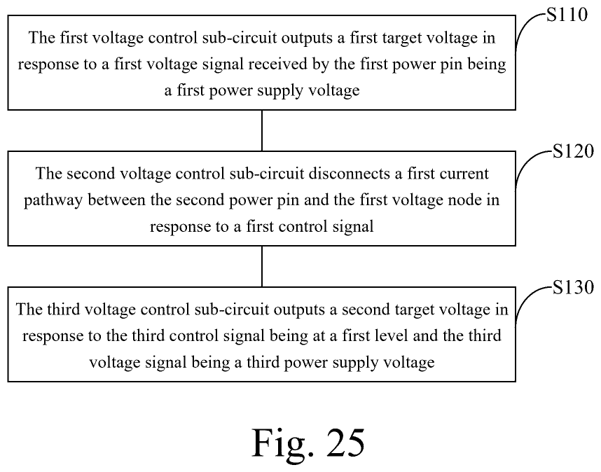

In some examples, the memory system further comprises a third voltage control sub-circuit coupled to the third power supply pin and the second voltage node. As shown in FIG. 25, the voltage control method further includes S130 in addition to S110 and S120. In S130, the third voltage control sub-circuit outputs a second target voltage in response to the third control signal being at a first level and the third voltage signal being a third power supply voltage. In an example, S110, S120, and S130 are executed simultaneously.

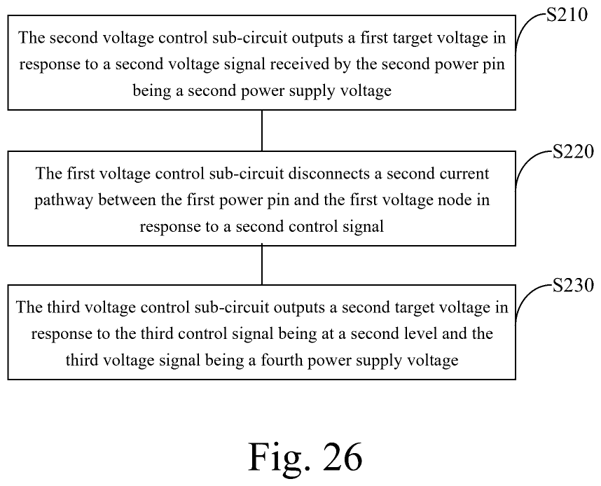

In other examples, as shown in FIG. 26, the voltage control method further includes S230 in addition to S210 and S220. In S230, the third voltage control sub-circuit outputs a second target voltage in response to the third control signal being at a second level and the third voltage signal being a fourth power supply voltage. In an example, S210, S220, and S230 are executed simultaneously.

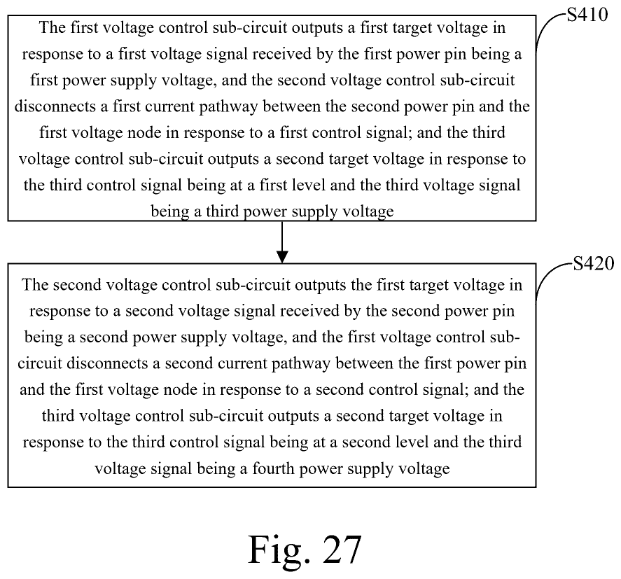

In some other examples, as shown in FIG. 27, the voltage control method includes:
S410: the first voltage control sub-circuit outputs a first target voltage in response to a first voltage signal received by the first power supply pin being a first power supply voltage, and the second voltage control sub-circuit disconnects a first current pathway between the second power supply pin and the first voltage node in response to a first control signal; and the third voltage control sub-circuit outputs a second target voltage in response to the third control signal being at a first level and the third voltage signal being a third power supply voltage; and
S420: the second voltage control sub-circuit outputs the first target voltage in response to a second voltage signal received by the second power supply pin being a second power supply voltage, and the first voltage control sub-circuit disconnects a second current pathway between the first power supply pin and the first voltage node in response to a second control signal; and the third voltage control sub-circuit outputs a second target voltage in response to the third control signal being at a second level and the third voltage signal being a fourth power supply voltage.

In an example, the first voltage control sub-circuit, the second voltage control sub-circuit, and the third voltage control sub-circuit perform operations synchronously in S410, and perform operations synchronously in S420.

In some examples, the third voltage control sub-circuit is coupled to the second power supply pin, and the third control signal is the second voltage signal. The third voltage control sub-circuit in S130 or S140 outputting the second target voltage in response to the third control signal being at the first level and the third voltage signal being the third power supply voltage comprises that: outputting the second target voltage based on the third power supply voltage in response to the second voltage signal being a first idle voltage.

Outputting the second target voltage in response to the third control signal being at the second level and the third voltage signal being the fourth power supply voltage in S230 or S240 comprises that: outputting the second target voltage based on the fourth power supply voltage in response to the second voltage signal being a second power supply voltage.

In some examples, the third voltage control sub-circuit includes a second voltage regulator and a second switch. The input terminal of the second voltage regulator is coupled to the third power supply pin, and the output terminal is coupled to the second voltage node. The two terminals of the second switch are connected in parallel to the two terminals of the second voltage regulator, and the control terminal is coupled to the second power supply pin.

The above operation of “outputting the second target voltage based on the third power supply voltage in response to the second voltage signal being the first idle voltage” comprises that: the second switch is in a turned-off state in response to the first idle voltage, and the second voltage regulator converts the third power supply voltage into the second target voltage.

The above operation of “outputting the second target voltage based on the fourth power supply voltage in response to the second voltage signal being the second power supply voltage” comprises that: the second switch is in a turned-on state in response to the second power supply voltage, to output the fourth power supply voltage as the second target voltage.

In some examples, the memory system further comprises a third voltage regulator coupled to the first voltage node. The voltage control method further comprises that: a third voltage regulator converts the first target voltage into a third target voltage.

The features disclosed in several device examples provided in the present disclosure may be combined arbitrarily to obtain a new device example without conflict.

The methods disclosed in several method examples provided in the present disclosure may be combined arbitrarily to obtain a new method example without conflict.

Examples of the present disclosure provide a voltage control circuit, a memory system, and a voltage control method.

In a first aspect of the present disclosure, a voltage control circuit is provided, comprising:
a first voltage control sub-circuit coupled to a first power supply pin and a first voltage node; and
a second voltage control sub-circuit coupled to a second power supply pin and the first voltage node,
wherein the first voltage control sub-circuit is configured to output a first target voltage in response to a first voltage signal received by the first power supply pin being a first power supply voltage, and the second voltage control sub-circuit is configured to disconnect a first current pathway between the second power supply pin and the first voltage node in response to a first control signal; and/or
the second voltage control sub-circuit is configured to output the first target voltage in response to a second voltage signal received by the second power supply pin being a second power supply voltage, and the first voltage control sub-circuit is configured to disconnect a second current pathway between the first power supply pin and the first voltage node in response to a second control signal.

In a second aspect of the present disclosure, a memory system is provided, comprising a voltage control circuit, and the voltage control circuit comprises:
a first voltage control sub-circuit coupled to a first power supply pin and a first voltage node; and
a second voltage control sub-circuit coupled to a second power supply pin and the first voltage node,
wherein the first voltage control sub-circuit is configured to output a first target voltage in response to a first voltage signal received by the first power supply pin being a first power supply voltage, and the second voltage control sub-circuit is configured to disconnect a first current pathway between the second power supply pin and the first voltage node in response to a first control signal; and/or
the second voltage control sub-circuit is configured to output the first target voltage in response to a second voltage signal received by the second power supply pin being a second power supply voltage, and the first voltage control sub-circuit is configured to disconnect a second current pathway between the first power supply pin and the first voltage node in response to a second control signal.

In a third aspect of the present disclosure, a voltage control method applied to a memory system is provided, the memory system comprises a first voltage control sub-circuit coupled to a first power supply pin and a first voltage node and a second voltage control sub-circuit coupled to a second power supply pin and the first voltage node, and the voltage control method comprises:
the first voltage control sub-circuit outputs a first target voltage in response to a first voltage signal received by the first power supply pin being a first power supply voltage, and the second voltage control sub-circuit disconnects a first current pathway between the second power supply pin and the first voltage node in response to a first control signal; and/or
the second voltage control sub-circuit outputs the first target voltage in response to a second voltage signal received by the second power supply pin being a second power supply voltage, and the first voltage control sub-circuit disconnects a second current pathway between the first power supply pin and the first voltage node in response to a second control signal.

In the present disclosure, at least one of the first power supply voltage and the second power supply voltage received by the voltage control circuit is different from the first target voltage, and the voltage control circuit may regulate the first power supply voltage and the second power supply voltage to the first target voltage. Thus, when the memory system comprising the voltage control circuit is integrated into the application platform, the voltage control circuit in the memory system may provide the first target voltage to the device no matter the power supply scheme of the application platform is to provide the first power supply voltage to the first power supply pin or to provide the second power supply voltage to the second power supply pin. As such, a memory system may simultaneously support both two power supply schemes without providing two memory systems for two power supply schemes, so that the research and development investment and cost may be reduced, and the platform compatibility and competitiveness of products may be improved.

The above are only some implementations of the present disclosure, but the scope of the present disclosure is not limited thereto. Variations or replacements which may be readily conceived by anyone skilled in the art within the technical scope disclosed in the present disclosure should be encompassed within the scope of the present disclosure.

What is claimed is:

1. A voltage control circuit, comprising:
a first voltage control sub-circuit coupled to a first power supply pin and a first voltage node; and
a second voltage control sub-circuit coupled to a second power supply pin and the first voltage node,
wherein at least one of:
the first voltage control sub-circuit is configured to output a first target voltage in response to a first voltage signal received by the first power supply pin being a first power supply voltage, and the second voltage control sub-circuit is configured to disconnect a first current pathway between the second power supply pin and the first voltage node in response to a first control signal; or
the second voltage control sub-circuit is configured to output the first target voltage in response to a second voltage signal received by the second power supply pin being a second power supply voltage, and the first voltage control sub-circuit is configured to disconnect a second current pathway between the first power supply pin and the first voltage node in response to a second control signal.

2. The voltage control circuit of claim 1, wherein at least one of:
the first control signal is the second voltage signal, and the second voltage control sub-circuit disconnects the first current pathway in response to the second voltage signal being a first idle voltage, or
the second control signal is the first voltage signal, and the first voltage control sub-circuit disconnects the second current pathway in response to the first voltage signal being a second idle voltage.

3. The voltage control circuit of claim 2, wherein:
the first voltage control sub-circuit comprises a first voltage regulator, an input terminal of the first voltage regulator being coupled to the first power supply pin, and an output terminal of the first voltage regulator being coupled to the first voltage node; and
the first voltage regulator is configured to convert the first power supply voltage into the first target voltage in response to the first voltage signal being the first power supply voltage.

4. The voltage control circuit of claim 3, wherein:
the second voltage control sub-circuit comprises a first switch, a first terminal and a control terminal of the first switch being coupled to the second power supply pin, and a second terminal of the first switch being coupled to the first voltage node; and
the first switch is configured to be in a turned-off state to disconnect the first current pathway in response to the second voltage signal being the first idle voltage.

5. The voltage control circuit of claim 4, wherein:
the first switch is configured to be in a turned-on state in response to the second voltage signal being the second power supply voltage to output the second power supply voltage as the first target voltage; and
the first voltage regulator is configured to stop operation to disconnect the second current pathway in response to the first voltage signal being the second idle voltage, wherein the second idle voltage is beyond an input range of the first voltage regulator.

6. The voltage control circuit of claim 4, further comprising a third voltage control sub-circuit coupled to a third power supply pin and a second voltage node and configured to at least one of:
output a second target voltage in response to a third control signal being at a first level and a third voltage signal received by the third power supply pin being a third power supply voltage, or
output the second target voltage in response to the third control signal being at a second level and the third voltage signal being a fourth power supply voltage.

7. The voltage control circuit of claim 6, wherein the third voltage control sub-circuit is coupled to the second power supply pin, and the third control signal is the second voltage signal; and
wherein the third control signal being at the first level indicates that the second voltage signal is the first idle voltage, and the third control signal being at the second level indicates that the second voltage signal is the second power supply voltage.

8. The voltage control circuit of claim 7, wherein the fourth power supply voltage is equal to the second target voltage, and the third voltage control sub-circuit comprises:
a second voltage regulator, wherein an input terminal of the second voltage regulator is coupled to the third power supply pin, an output terminal of the second voltage regulator is coupled to the second voltage node, and the second voltage regulator is configured to convert the third power supply voltage into the second target voltage in response to the third voltage signal being the third power supply voltage; and
a second switch, wherein a first terminal and a second terminal of the second switch are connected in parallel to the input terminal and the output terminal of the second voltage regulator, a control terminal of the second switch is coupled to the second power supply pin, and the second switch is at least one of configured to be in a turned-off state in response to the second voltage signal being the first idle voltage or configured to be in a turned-on state in response to the second voltage signal being the second power supply voltage, to output the fourth power supply voltage as the second target voltage.

9. The voltage control circuit of claim 8, wherein both the first switch and the second switch are NMOS transistors; and
both the first voltage regulator and the second voltage regulator are low dropout linear regulators.

10. The voltage control circuit of claim 6, wherein the third voltage control sub-circuit is coupled to the first power supply pin, and the third control signal is the first voltage signal; and
wherein the third control signal being at the first level indicates that the first voltage signal is the first power supply voltage, and the third control signal being at the second level indicates that the first voltage signal is the second idle voltage.

11. The voltage control circuit of claim 10, wherein the fourth power supply voltage is equal to the second target voltage, and the third voltage control sub-circuit comprises:
a second voltage regulator, wherein an input terminal of the second voltage regulator is coupled to the third power supply pin, an output terminal of the second voltage regulator is coupled to the second voltage node, and the second voltage regulator is configured to convert the third power supply voltage into the second target voltage in response to the third voltage signal being the third power supply voltage; and
a third switch, wherein a first terminal and a second terminal of the third switch are connected in parallel to the input terminal and the output terminal of the second voltage regulator, a control terminal of the third switch is coupled to the first power supply pin, and the third switch is at least one of configured to be in a turned-off state in response to the first voltage signal being the first power supply voltage or configured to be in a turned-on state in response to the first voltage signal being the second idle voltage, to output the fourth power supply voltage as the second target voltage.

12. A memory system, comprising:
a voltage control circuit comprising:
a first voltage control sub-circuit coupled to a first power supply pin and a first voltage node; and
a second voltage control sub-circuit coupled to a second power supply pin and the first voltage node,
wherein at least one of:
the first voltage control sub-circuit is configured to output a first target voltage in response to a first voltage signal received by the first power supply pin being a first power supply voltage, and the second voltage control sub-circuit is configured to disconnect a first current pathway between the second power supply pin and the first voltage node in response to a first control signal; or
the second voltage control sub-circuit is configured to output the first target voltage in response to a second voltage signal received by the second power supply pin being a second power supply voltage, and the first voltage control sub-circuit is configured to disconnect a second current pathway between the first power supply pin and the first voltage node in response to a second control signal.

13. The memory system of claim 12, further comprising a package substrate and a die located on the package substrate,
wherein the voltage control circuit is located on the package substrate.

14. The memory system of claim 13, wherein the die further comprises:
a third voltage regulator coupled to the first voltage node and configured to convert the first target voltage into a third target voltage.

15. The memory system of claim 14, wherein the memory system is a Universal Flash Storage, and the die comprises:
a physical layer and a controller core coupled to the third voltage regulator; and
a memory device input/output in a memory controller and a memory device input/output in a memory device coupled to the first voltage node.

16. The memory system of claim 15, wherein the voltage control circuit further comprises:
a third voltage control sub-circuit coupled to a third power supply pin and a second voltage node, and at least one of configured to output a second target voltage in response to a third control signal being at a first level and a third voltage signal received by the third power supply pin being a third power supply voltage or configured to output the second target voltage in response to the third control signal being at a second level and the third voltage signal being a fourth power supply voltage; and
wherein the die further comprises a peripheral circuit of the memory device coupled to the second voltage node.

17. A voltage control method applied to a memory system, wherein the memory system comprises a first voltage control sub-circuit coupled to a first power supply pin and a first voltage node and a second voltage control sub-circuit coupled to a second power supply pin and the first voltage node, and the voltage control method comprises:
outputting a first target voltage, by the first voltage control sub-circuit, in response to a first voltage signal received by the first power supply pin being a first power supply voltage; or
outputting the first target voltage, by the second voltage control sub-circuit, in response to a second voltage signal received by the second power supply pin being a second power supply voltage; and
disconnecting a first current pathway between the second power supply pin and the first voltage node, by the second voltage control sub-circuit, in response to a first control signal; or
disconnecting a second current pathway between the first power supply pin and the first voltage node, by the first voltage control sub-circuit, in response to a second control signal.

18. The voltage control method of claim 17, wherein:
the first control signal is the second voltage signal, and disconnecting the first current pathway between the second power supply pin and the first voltage node by the second voltage control sub-circuit in response to the first control signal comprises: disconnecting the first current pathway by the second voltage control sub-circuit in response to the second voltage signal being a first idle voltage; and
the second control signal is the first voltage signal, and disconnecting the second current pathway between the first power supply pin and the first voltage node by the first voltage control sub-circuit in response to the second control signal comprises: disconnecting the second current pathway by the first voltage control sub-circuit in response to the first voltage signal being a second idle voltage.

19. The voltage control method of claim 18, wherein:
the first voltage control sub-circuit comprises a first voltage regulator, an input terminal of the first voltage regulator is coupled to the first power supply pin and an output terminal of the first voltage regulator is coupled to the first voltage node;
the second voltage control sub-circuit comprises a first switch, a first terminal and a control terminal of the first switch are coupled to the second power supply pin, and a second terminal of the first switch is coupled to the first voltage node;
outputting the first target voltage by the first voltage control sub-circuit in response to the first voltage signal received by the first power supply pin being the first power supply voltage comprises that: the first voltage regulator receives the first power supply voltage and converts the first power supply voltage into the first target voltage; and
disconnecting the first current pathway by the second voltage control sub-circuit in response to the second voltage signal being the first idle voltage comprises that: the first switch is in a turned-off state in response to the first idle voltage to disconnect the first current pathway.

20. The voltage control method of claim 19, wherein:
outputting the first target voltage by the second voltage control sub-circuit in response to the second voltage signal received by the second power supply pin being the second power supply voltage comprises that: the first switch is in a turned-on state in response to the second power supply voltage to output the second power supply voltage as the first target voltage; and
disconnecting the second current pathway by the first voltage control sub-circuit in response to the first voltage signal being the second idle voltage comprises that: the first voltage regulator stops operation in response to the second idle voltage to disconnect the second current pathway, wherein the second idle voltage is beyond an input range of the first voltage regulator.
